(19) United States
(12) Patent Application Publication
(10) Pub. No.: US 2008/0093111 A1
(43) Pub. Date: Apr. 24, 2008

(54) MULTILAYER WIRING BOARD AND METHOD OF MANUFACTURING THE SAME

(75) Inventor: Mitsuyuki TSURUMI, Ashigarakami-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 11/877,196

(22) Filed: Oct. 23, 2007

(30) Foreign Application Priority Data
Oct. 23, 2006 (JP) 2006-287880

(51) Int. Cl. H05K 1/09; H05K 3/20

(52) U.S. Cl. 174/257; 29/831

(57) ABSTRACT

The invention provides a multilayer wiring board including wiring patterns formed with a multilayer structure with at least one electrical insulating layer interposed therebetween, the wiring patterns being electrically connected with each other through at least one via formed in the insulating layer(s). The multilayer wiring board includes at least one wiring containing layer on one side or both sides of a substrate, or of a circuit board having a predetermined wiring pattern. The wiring containing layer includes: a wiring forming layer, formed by disposing in this order an insulating layer, a chemically active site generating layer, which can interact with the insulating layer and which can interact with a reactive polymer compound containing layer, the reactive polymer compound containing layer that can interact with the chemically active site generating layer and that can interact with the conductor layer, and then applying energy to the wiring forming layer so as to cause interaction between the chemically active site generating layer and the reactive polymer compound containing layer; and the conductor layer disposed on the wiring forming layer.

### CROSS-REFERENCE TO RELATED APPLICATION

This Application claims priority under 35 USC 119 from Japanese Patent Application No. 2006-287880, the disclosure of which is incorporated by reference herein.

### BACKGROUND OF THE INVENTION

1. Field of the Invention

The present invention relates to a printed wiring board and a method of manufacturing the same, and in particular, to a printed wiring board having a high density wiring that is used in the field of electronic materials. More particularly, the invention relates to a method of manufacturing a wiring board that is formed by laminating wiring layers with an electrical insulating layer interposed therebetween.

2. Description of the Related Art

In recent years, along with the demands for high performance electronic apparatuses, electronic components are being increasingly integrated at higher densities and mounted at higher densities. Therefore, printed wiring boards applicable to such high mounting densities are also reducing in size and increasing in density. Various methods are being studied to meet the high density of the printed wiring boards and the like. For example, forming stable high-definition wiring, using a buildup multilayer wiring board, and the like are being examined. Furthermore, there is a product that is formed by laminating wiring layers through a buildup method. In this case, electrical insulating layers are connected with each other through fine vias.

“Subtractive methods” and “Semi-additive methods” have been known as methods of forming metal patterns, which are useful in the field of known conductive patterns, particularly for known printed wiring boards. In the subtractive methods, a photosensitive layer, onto which actinic light is irradiated, is formed on a metal layer that is formed on a substrate. Next, the photosensitive layer is subjected to imagewise exposure and development to form a resist image. Subsequently, the metal is etched to form a metal pattern, and the resist is removed. Here, a metal substrate to be used has an interface that is roughened to give adhesiveness between the substrate and the metal layer, such that adhesiveness is generated due to an anchor effect. As a result, the interface of the metal pattern to the substrate is made uneven. For this reason, when the metal pattern is used as electric wiring, high frequency characteristics may be deteriorated. In addition there is the problem that, since the substrate is roughened when the metal substrate is formed, a troublesome process for treating the substrate with a strong acid, such as a chromium acid, is needed.

In the semi-additive methods, first, a power feed layer is provided on the surface of an electrical insulating layer by one method or another. Next, a photosensitive layer, for irradiating actinic light thereon, is formed on the power feed layer, and the photosensitive layer is subjected to imagewise exposure and development to form a resist image. Subsequently, current is supplied to the power feed layer to perform electroplating, to thereby form metal wiring on portions where the resist does not exist. Finally, etching is performed on portions of the power feed layer where the metal wiring does not exist, thereby forming a metal pattern. A plating method, a sputtering method, or an evaporation method may be used as the method of forming the power feed layer. When the power feed layer is formed by a plating method, similarly to the subtractive method, the surface of the electrical insulating layer is roughened to give adhesiveness between the substrate and the power feed layer, such that adhesiveness is generated due to an anchor effect. As a result, the interface of the metal pattern to the substrate is made uneven. For this reason, when the metal pattern is used as electric wiring, high frequency characteristics may be deteriorated. In addition there is the problem that, since the substrate is roughened when the metal substrate is formed, a troublesome process for treating the substrate with a strong acid, such as a chromium acid, is needed. Meanwhile, since large-scale vacuum facilities are needed to form the power feed layer by a sputtering method or an evaporation method, the sputtering method and the evaporation method are not suitable for a multilayer board.

As described above, when wiring patterns are laminated with substrates or electrical insulating layers interposed therebetween, the adhesiveness between the electrical insulating layer and the wiring pattern is an issue. For example, when a metal layer is formed on the electrical insulating layer by electrolytic plating, adhesiveness depends on adhesiveness between the insulating layer and the layer that is used as the power feed layer for electroplating. However, there is a problem in this case when the surface of the electrical insulating layer is roughened and adhesiveness is generated by an anchor effect. That is, as wiring becomes fine and the space between wiring lines becomes narrow, the amount of irregularities must be made small so as not to affect the shape of the wiring. Accordingly, it may be impossible to obtain sufficient adhesion.

In order to solve this problem, there is known a method that includes grafting a radical polymerizable compound on the surface of the substrate to modify surface properties and minimize the irregularities of the substrate, thereby simplifying the treatment of the substrate (for example, see Japanese Patent Application Laid-Open (JP-A) No. 58-196238). However, an expensive apparatus (a γ-ray generator or an electron beam generator) is needed to perform this method. Furthermore, since a plastic substrate that is generally commercially available is used as the substrate, the graft polymer may not be generated sufficiently to provide the adhesive strength required to adhere conductive material to the substrate, and the adhesion between the substrate and the conductive layer may not reach a practical strength level.

As a method of forming a conductive layer, there is proposed a method of accumulating gold nanoparticles on one layer using a surface graft polymer, which has a polymer terminal fixed to the surface of a substrate (for example, see P 15120, 99th volume, “J. Phys. Chem.” (1995) written by Liz-Marzan, L. M. et al. and P 2993, 100th volume, “Mol. Phys.” (2002) written by Carignano, M. A. et al.). In this method, a polyacrylamide brush formed on a glass surface is immersed in a dispersion liquid, which contains gold nanoparticles having negative electric charges and has a low pH value (about 6.5), for one night. As a result, a film, in which nanoparticles are three-dimensionally accumulated, is formed due to electrostatic interaction between an amide group (—NH₃⁺) having positive electric charges and nanoparticles having negative electric charges. However, under the conditions disclosed therein, interaction is not generated at a level that is satisfactory in practice by the accumulation phenomenon that is caused by electrostatic force between the charged polymer and the charged particles. There is a need in practice for an improvement in the adhesiveness of conductive materials.

A process of applying energy while components used as raw materials of the graft polymer are in contact with the surface of the substrate is needed to form the surface graft polymer. In addition, it is difficult to maintain uniform contact, and in particular to maintain uniformity of a process that is repeatedly performed several times when a multilayer printed wiring board is produced.

### SUMMARY OF THE INVENTION

The present invention has been made in view of the above circumstances.

The invention provides a multilayer wiring board that has excellent adhesiveness to an insulating film, a small level of irregularities at the interface with the insulating film, and high-definition wiring.

Further, the invention provides a method of simply and easily manufacturing a multilayer wiring board. In the method, a conductive layer, which has excellent adhesiveness to an insulating film and small irregularities at the interface with the insulating film, can be easily formed on a surface of a solid, such as an insulating film, on which wiring has been formed beforehand.

According to a first aspect of the invention, there is provided a multilayer wiring board including wiring patterns formed with a multilayer structure with at least one electrical insulating layer interposed therebetween, the wiring patterns being electrically connected with each other by at least one via formed in the insulating layer(s), the multilayer wiring board including at least one wiring containing layer on one side or both sides of a substrate, or of a circuit board having a predetermined wiring pattern, the wiring containing layer including: a wiring forming layer, formed by disposing in this order an insulating layer, a chemically active site generating layer, and a reactive polymer compound containing layer, and then applying energy to the wiring forming layer so as to cause interaction between the chemical active site generating layer and the reactive polymer compound containing layer; and a conductor layer disposed on the wiring forming layer, wherein the chemically active site generating layer is able to interact with the insulating layer and is able to interact with the reactive polymer compound containing layer, and the reactive polymer compound containing layer is able to interact with the chemically active site generating layer and is able to interact with the conductor layer.

According to a second aspect of the invention, there is provided a multilayer wiring board including wiring patterns formed with a multilayer structure with at least one electrical insulating layer interposed therebetween, the wiring patterns being electrically connected with each other by at least one via formed in the insulating layers, the multilayer wiring board including at least one wiring containing layer on one side or both sides of a substrate, or of a circuit board having a predetermined wiring pattern, the wiring containing layer including: a wiring forming layer, formed by disposing in this order an insulating layer having polymerization initiating ability and a reactive polymer compound containing layer, and then applying energy to the wiring forming layer so as to cause interaction between the insulating layer having polymerization initiating ability and the reactive polymer compound containing layer; and a conductor layer disposed on the wiring forming layer, wherein the insulating layer having polymerization initiating ability is able to interact with the reactive polymer compound containing layer, and the reactive polymer compound containing layer is able to interact with the insulating layer having polymerization initiating ability and is able to interact with the conductor layer.

According to a third aspect of the invention, there is provided a method of manufacturing the multilayer wiring board according to the first aspect. The method includes: forming an insulating layer by applying, to one side or both sides of a substrate, or of a circuit board having a predetermined wiring pattern, an electrical insulating layer forming material by some method, such as a coating method or a transfer method, and curing the material by energy application; forming, on the insulating layer, a chemically active site generating layer, which can interact with the insulating layer and which can interact with a reactive polymer compound containing layer that can interact with a conductor layer; forming, on the chemically active site generating layer, the reactive polymer compound containing layer, to which can be adhered a conductive material or a precursor thereof for forming the conductor layer; adhering the reactive polymer compound containing layer to the chemically active site generating layer using interaction therebetween; forming at least one hole in the laminate, which includes the insulating layer, the chemically active site generating layer, and the reactive polymer compound containing layer; applying a conductive material, or a precursor thereof, to a polymer compound of the reactive polymer compound containing layer; forming the conductor layer by performing plating using the conductive material, or the precursor thereof, that has been applied to the reactive polymer compound containing layer; connecting a plurality of wiring lines to each other by applying a conductive material to the hole; and performing heat treatment after the forming of the conductor layer.

According to a fourth aspect of the invention, there is provided a method of manufacturing the multilayer wiring board according to the second aspect. The method includes: forming an insulating layer having polymerization initiating ability by applying, to one side or both sides of a substrate, or of a circuit board having a predetermined wiring pattern, an electrical insulating layer forming material containing a polymerization initiator by some method, such as a coating method or a transfer method, and curing the material by energy application; forming on the insulating layer having polymerization initiating ability a reactive polymer compound containing layer, to which a conductive material or a precursor thereof for forming a conductor layer can be adhered; adhering the reactive polymer compound containing layer to the insulating layer having polymerization initiating ability using interaction therebetween; forming at least one hole in the laminate, which includes the insulating layer having polymerization initiating ability and the reactive polymer compound containing layer; applying a conductive material, or a precursor thereof, to a polymer compound of the reactive polymer compound containing layer; forming the conductor layer by performing plating with the conductive material, or the precursor thereof, that has been applied to the reactive polymer compound containing layer; connecting a plurality of wiring lines to each other by applying a conductive material into the hole; and performing heat treatment after the forming of the conductor layer.

In this case, the forming of the (a) insulating layer and the forming of the (b) chemically active site generating layer may be performed at the same time. Alternatively, the forming of the (b) chemically active site generating layer may be performed after the forming of the (a) insulating layer. Further, the forming of the (a) insulating layer, the forming of the (b) chemically active site generating layer, and the forming of the (c) reactive polymer compound containing layer may be performed at the same time. Alternatively, the forming of the (c) reactive polymer compound containing layer may be performed after the forming of the (a) insulating layer and the forming of the (b) chemically active site generating layer.

After the (c) reactive polymer compound containing layer has been formed, the (d) conductor layer may be formed by plating.

If the method of manufacturing the multilayer wiring board according to the invention is applied, it is possible to easily form a conductor layer, which has excellent adhesiveness to an insulating layer, on a substrate or on wiring formed on an insulating film.

In the method of manufacturing the multilayer wiring board according to the invention, it is possible to manufacture a multilayer wiring board, such as a finished printed wiring board obtained by, after a metallic conductor pattern is formed, forming a solder resist, forming a protective layer, and/or performing a surface treatment and/or routing.

By forming a reactive polymer compound containing layer on the entire surface, and performing energy application (exposure) to the entire surface, it is possible to form a conductor layer forming conductive material over the entire surface of an insulating film on, for example, a copper-clad laminate used for forming a printed wiring board. The conductive material can be used as a material for a wiring board that is formed using a subtractive method.

According to the invention, by performing pattern exposure it is possible to form a reactive polymer compound containing layer, which is used to form a conductor layer in a predetermined region. As such an application, it is possible to form predetermined wiring using pattern exposure. That is, it is possible to prevent a reactive polymer compound containing layer and a seed layer from being formed in regions where metal wiring is not to be formed, such as holes. If a conductor layer is not formed at portions where holes are to be formed, it is possible to form holes easily and to prevent the waste of conductive material. In addition, when the reactive polymer compound containing layer is formed on the bottom surface or the side surface of holes, and seeds, such as a conductive material or a precursor thereof are applied to the reactive polymer compound containing layer after the holes are formed, it is possible to easily form the conductor layer to the via holes by plating.

### DETAILED DESCRIPTION OF THE INVENTION

Embodiments of the present invention will be described in detail.

A multilayer wiring board according to an aspect of the invention includes wiring patterns electrically connected with each other by via holes formed in insulating layers, and includes at least one wiring containing layer on one side or both sides of a substrate or a circuit board having a predetermined wiring pattern. Each of the wiring containing layers has a structure of an (a) insulating layer that has an electrical insulation property, a (b) chemically active site generating layer that is formed on the (a) insulating layer, and can interact with the electrical insulating layer and a reactive polymer compound containing layer, which interacts with a conductor layer, the (c) reactive polymer compound containing layer that can interact with the chemically active site generating layer and the conductor layer, and the (d) conductor layer in that order from a surface of a substrate.

The (a) insulating layer may be an (a-2) insulating layer having polymerization initiating ability that can directly interact with the (c) reactive polymer compound containing layer, and in this case, the (b) chemically active site generating layer does not need to be particularly formed.

A method of manufacturing a wiring board according to an embodiment of the invention relates to a method of manufacturing a wiring board by interposing an electrical insulating layer between layers to laminate wiring layers, and a method of manufacturing a wiring board by forming a wiring layer on an insulating substrate. In particular, the method of manufacturing a wiring board according to an aspect of the invention relates to a method of manufacturing a wiring board, in which plating is performed on a surface of an electrical insulating layer to deposit and form a conductor layer.

The method of manufacturing a wiring board according to an aspect of the invention will be described in detail below. In the method, the following processes may be performed on a surface of one side or both sides of a substrate or a circuit board having a predetermined wiring pattern as a base, as necessary, in no particular order. That is, the method may include: a (I) process of forming an insulating layer by applying an electrical insulating layer forming material by some method, such as a coating method or a transfer method, and curing the material by energy application; a (II) process of forming, on the insulating layer, a chemically active site generating layer that can interact with a reactive polymer compound containing layer, which can interact with the insulating layer and a conductor layer; a (III) process of forming, on the chemically active site generating layer, a reactive polymer compound containing layer, to which a conductive material or a precursor thereof for forming can be adhered; a (IV) process of adhering the reactive polymer compound containing layer to the chemically active site generating layer using an interaction therebetween; a (V) process of forming one or more hole in a laminate, which includes the insulating layer, the chemically active site generating layer, and the reactive polymer compound containing layer, for connection to a predetermined wiring pattern of a circuit board; a (VI) process of applying a conductive material or a precursor thereof to a polymer compound of the reactive polymer compound containing layer; a (VII) process of forming a conductor layer by performing plating with the conductive material or the precursor thereof, which is applied to the reactive polymer compound containing layer; a (VIII) process of connecting a plurality of wirings to each other by applying a conductive material into the holes; and a (IX) process of performing a heat treatment after the forming of the conductor layer.

The processes may be sequentially performed or may be performed at the same time, if necessary. If not necessary, one or some of the processes may be omitted. The (II) process of forming the chemically active site generating layer is performed at the same time as the (I) process of forming the insulating layer or after the (I) process, the (III) process of forming the reactive polymer compound containing layer is performed at the same time as the (I) process of forming the electrical insulating layer or the (II) process of forming the chemically active site generating layer or after the (I) and (II) processes. In addition, the (VII) process of forming the conductor layer by plating is performed after the (III) process of forming the reactive polymer compound containing layer.

The components of each layer and each process will be described below.

<Substrate>

Those generally called a core substrate or an inner layer-circuit board, may be used as the substrate or the circuit board that has a predetermined wiring pattern as a base.

Examples of the substrate or a substrate of the inner layer-circuit board having a circuit include a substrate formed of a base material, such as glass epoxy, metal, polyester, polyimide, thermosetting polyphenylene ether, polyamide, polyaramide, paper, glass cross, glass nonwoven fabric, or liquid crystalline polymer, a substrate formed of a resin, such as a phenol resin, an epoxy resin, an imide resin, a BT resin, a PPE resin, or a tetrafluoroethylene resin, a silicon board, and a ceramic board. Examples of the circuit board include a copper clad laminated board in which wiring is formed on such substrate (base material).

The surface of a circuit or a base material forming the insulating layer may be roughened beforehand or not be roughened.

Meanwhile, in recent years, a substrate formed by laminating insulating films, which do not include glass cross or nonwoven fabric, may be used as a coreless substrate. Furthermore, a flexible printed board or a resin film base that is formed of polyimide or liquid crystalline polymer and used in the flexible printed board may be used depending on the intended purpose.

In addition, a board, on which a polishing for forming fine irregularities has been performed to make the surface thereof uniform or to improve the adhesion to the insulating layer used as an upper layer, may be used as the above-mentioned board.

Examples of the polishing process may include mechanical polishing, such as buffing, belt polishing, and pumice polishing. Further, chemical polishing, chemical-mechanical polishing, electrolytic polishing, or the like may be performed instead of the mechanical polishing.

When an insulating layer to be described below is formed on the circuit board having previously formed wiring board, an etching process for removing an oxide film from the copper surface may be performed. Further, a treatment, such as a blackening treatment, may be performed beforehand on the surface of a conductor circuit.

<(a) Insulating Layer>

Known insulating resin compositions, which have been used for a multilayer laminated board, a buildup board, or a flexible board in the related art, may be used to form the electrical insulating layer according to the invention. Various additives may be used together with the insulating resin compositions depending on the purpose.

For example, a polyfunctional acrylate monomer may be added to increase the strength of the insulating layer, and inorganic or organic particles may be added to increase the strength of the insulator layer and to improve electrical characteristics of the insulator layer.

Meanwhile, the “insulating resin” used herein means a resin that has an insulation property capable of being used in a known insulating film. Furthermore, any insulating resin, not an absolute insulator, can be used insofar as it has an insulation property at a level appropriate for the purpose.

Specific examples of the insulating resin include a thermosetting resin, a thermoplastic resin, and a mixture thereof. Examples of the thermosetting resin include an epoxy resin, a phenol resin, a polyimide resin, a polyester resin, a bismaleimide resin, a polyolefin-based resin, and a isocyanate-based resin.

Examples of the epoxy resin include a cresol novolac epoxy resin, a bisphenol A epoxy resin, a bisphenol F epoxy resin, a phenol novolac epoxy resin, an alkyl phenol novolac epoxy resin, a bisphenol F epoxy resin, a naphthalene epoxy resin, a dicyclopentadiene epoxy resin, an epoxy compound of a condensation product of a phenol and an aromatic aldehyde having a phenolic hydroxyl group, triglycidyl isocyanurate, and an alicyclic epoxy resin. These resins may be used alone, or two or more of these resins may be used in combination. Accordingly, the resultant insulating layer may have excellent heat resistance.

Examples of the polyolefin-based resin include a polyethylene-based resin, a polystyrene-based resin, a polypropylene-based resin, a polyisobutylene-based resin, a polybutadiene-based resin, a polyisoprene-based resin, a cycloolefin-based resin, and copolymers of these resins.

Examples of the thermoplastic resin include a phenoxy resin, polyether sulfon, polysulfone, polyphenylene sulfon, polyphenylene sulfide, polyphenyl ether, and polyetherimide. Examples of the thermoplastic resin include (1) 1,2-bis(vinylphenylene)ethane resin or a modified resin formed of the 1,2-bis(vinylphenylene)ethane resin and a polyphenylene ether resin (disclosed in Amou, S. et al., Journal of Applied Polymer Science Vol. 92, 1252-1258 (2004)), (2) liquid crystalline polymer, specifically, VECSTER manufactured by Kuraray Co., Ltd., and (3) fluorocarbon polymer (PTFE).

The thermoplastic and thermosetting resins may be used alone, or two or more of the thermoplastic and thermosetting resins may be used in combination. The thermoplastic and thermosetting resins are used in combination to cover individual demerits and to obtain excellent effects. For example, since the thermoplastic resin, such as polyphenylene ether (PPE), has low heat resistance, the thermoplastic resin may be alloyed with the thermosetting resin. For example, PPE may be alloyed with epoxy, or triallyl isocyanurate, or a PPE resin containing a polymerizable functional group may be alloyed with another thermosetting resin. A Cyanate ester has the most excellent dielectric characteristic among the thermosetting resins, but it is rarely used alone and may be used as a modified resin with an epoxy resin, a maleimide resin, a thermoplastic resin or the like. The detailed descriptions thereof are disclosed in Electronic Technology (2002/No. 9, P 35). In addition, the thermosetting resin, which includes an epoxy resin and/or a phenol resin, and the thermoplastic resin, which includes a phenoxy resin and/or polyether sulfon (PES), may be used to improve dielectric characteristics.

The insulating resin composition may contain a compound having a polymerizable double bond, such as an acrylate or a methacrylate compound, to progress crosslinking. In particular, the compound having a polymerizable double bond is preferably a polyfunctional compound. In addition, a thermosetting resin or a thermoplastic resin may be used as a compound having a polymerizable double bond. For example, a resin that is formed by causing part of epoxy resin, phenol resin, polyimide resin, polyolefin resin, or fluororesin to suffer from a (metha)acrylic reaction using methacrylic acid or acrylic acid.

According to the invention, a composite (composite material) formed of a resin and other components may be used in the insulating resin composition in order to improve characteristics, such as mechanical strength, heat resistance, antiweatherability, fire retardancy, water resistance, and electrical characteristics of a resin film. Examples of the material for forming a composite include paper, fiberglass, silica particles, a phenol resin, a polyimide resin, a bismaleimide triazine resin, a fluorocarbon polymer, and a polyphenylene oxide resin.

Further, fillers that are used in a resin material for a general wiring board, for example, inorganic fillers, such as a silica, alumina, clay, talc, aluminum hydroxide, and calcium carbonate, and organic fillers, such as a hardened epoxy resin, a crosslinked benzoguanamine resin, and a crosslinked acrylic polymer, may be contained alone or in combination in the insulating resin composition, if necessary.

In addition, additive agents, such as a coloring agent, a fire retardant, an adhesion applying agent, a silane coupling agent, an anti-oxidizing agent, and an ultraviolet absorbing agent, may be added alone or in combination to the insulating resin composition, if necessary.

When such material is added to the active species generating composition, the amount thereof is preferably in a range of 1 to 200% by mass with respect to the resin, and more preferably, in a range of 10 to 80% by mass with respect to the resin. When the amount of the added material is smaller than 1% by mass, the above-mentioned characteristics may not be improved. Meanwhile, when the amount of the added material is larger than 200% by mass, characteristics, such as the strength of a resin, may be deteriorated.

The multilayer wiring board according to the invention has a laminate structure in which the (a) insulating layer, the (b) chemically active site generating layer, the (c) reactive polymer compound containing layer, and the (d) conductor layer are disposed in this order. However, when the (a) insulating layer is intended to directly interact with the (c) reactive polymer compound containing layer in order to be adhered to the (c) reactive polymer compound containing layer, a compound that generates active sites capable of causing the interaction with the (c) reactive polymer compound containing layer may be added to form the (a-2) insulating layer having polymerization initiating ability when energy is applied to the (a) insulating layer. In this case, the (b) chemically active site generating layer is not necessarily required. The (a-2) insulating layer having polymerization initiating ability may be formed of an insulating resin material having polymerization initiating ability, or may be obtained by adding a compound having polymerization initiating ability to the insulating resin material. The (a-2) insulating layer having polymerization initiating ability is included in the (a) insulating layer of the invention, and hereinafter the (a-2) insulating layer and the (a) insulating layer may be collectively simply called the “(a) insulating layer”.

Examples of the compound, which is contained in the (a-2) insulating layer having polymerization initiating ability and generates active sites capable of causing the interaction with the (c) reactive polymer compound containing layer, may include a thermal polymerization initiator and a photopolymerization initiator. Examples of thermal polymerization initiator include a peroxide initiator, such as benzoyl peroxide or azoisobutyronitrile, and an azo-based initiator. Further, a known material may be used as the photopolymerization initiator, and a low molecular compound or a polymer compound may be used as the photopolymerization initiator. Furthermore, when the (a) insulating layer is an (a-2) insulating layer having polymerization initiating ability, which is formed of a material capable of generating active sites interacting with the (c) reactive polymer compound containing layer due to energy application, a compound capable of generating active species does not need to be specially added.

Examples of the low-molecular-weight photopolymerization initiator include known radical generators, such as acetophenones, benzophenones, Michler's ketone, benzoylbenzoate, benzoins, α-acyloxime ester, tetramethylthiuram monosulfide, trichloromethyl triazine, and thioxanthone. Further, sulfonium salt or iodonium salt, which is used as a photoacid generator in general, may be used since it functions as a radical generator by light irradiation. Furthermore, a sensitizer may be used in addition to the photo-radical polymerization initiator to improve sensitivity. Examples of the sensitizer include n-butylamine, triethylamine, tri-n-butylphosphine, and thioxanthone derivatives.

Examples of a polymer photo-radical generator (high-molecular-weight photopolymerization initiator) include a polymer compound having an active carbonyl group on a side chain thereof, which is disclosed in JP-A Nos. 09-77891 and 10-45927.

The content of the polymerization initiator in the insulating resin is determined according to the purpose of the surface graft material to be used. In general, the content of the polymerization initiator is preferably in a range of approximately 0.1 to 50% by mass of a solid content in the insulator layer, and more preferably, in a range of approximately 1.0 to 30.0% by mass of a solid content in the insulator layer.

Here, the thickness of the insulating layer is generally in a range of 1 μm to 10 mm, and preferably, in a range of 10 to 1000 μm.

From the viewpoint of improving physical properties of a conductive layer to be formed, an average roughness (Rz) of the insulating film formed of an insulating resin, which is measured by a 10-point average height method according to JIS B 0601 (1994), the disclosure of which is incorporated by reference herein, is preferably 3 μm or less, and more preferably, 1 μm or less. The insulating layer having the surface smoothness in the above-mentioned range, that is, the insulating layer which does not actually have irregularities is preferably used to manufacture a printed wiring board having an extremely-fine circuit (for example, a circuit pattern of which values of line/space are 25/25 μm or less).

(Formation of Insulating Layer)

The insulating layer is formed on a surface of one side or both sides of a substrate used or a circuit board having a predetermined wiring pattern, used as a base, using a coating method, a transfer method, or a printing method.

(I. Transfer Method)

When an electrical insulating layer is formed by transfer, a film for forming an insulating layer is formed by coating a coating liquid, which is prepared to have improved coating characteristics by dissolving the components for forming the electrical insulating layer in a suitable solvent or forming the components in form of a varnish, on a support and drying the coating liquid. Subsequently, the film is transferred to form the electrical insulating layer. Since the film for forming the insulating layer is formed beforehand in the shape of a film, the film has high thickness accuracy and improved handleability and positioning accuracy. For this reason, the film for forming the insulating layer can be suitably used as a film for forming an insulating layer for various electronic components, or an interlayer adhesion film.

A general organic solvent may be used as a solvent that can be used to form a film. Any one of a hydrophilic solvent and a hydrophobic solvent may be used as the organic solvent. For example, a solvent for dissolving a thermosetting resin and a thermoplastic resin are preferably used. Specific examples of the solvent include an alcohol-based solvent, such as methanol, ethanol, 1-methoxy-2-propanol, or isopropyl alcohol, a ketone-based solvent, such as aceton, methyl ethyl ketone, or cyclohexaneone, an ether-based solvent, such as tetrahydrofuran, ethylene glycol monomethyl ether, ethylene glycol monobutyl ether, ethylene glycol monoethyl ether, or a nitrile-based solvent, such as acetonitrile. In addition, N-methyl-2-pyrolidone, N,N-dimethyl acetamide, N,N-dimethylformamide, ethylene glycol monomethyl ether, and tetrahydrofuran may also be used. Furthermore, acetic esters, such as ethyl acetate, butyl acetate, isopropyl acetate, cellosolve acetate, propylene glycol monomethyl ether acetate, or carbitol acetate, cellosolves, such as cellosolve or butyl cellosolve, carbitols, such as carbitol or butyl carbitol, aromatic hydrocarbon, such as toluene, xylene, benzen, naphthalene, hexan, or cyclohexane, dimethylformamide, dimethyl acetamide, and N-methylpyrrolidone may be used. The solvents may be used alone or two or more of the solvents may be used in combination.

From the viewpoints of viscosity, workability, coating characteristics, drying time, and working efficiency of the coating liquid or varnish, the blending amount of the solvent for the coating liquid or the varnish is preferably in a range of 5 to 2000 parts by weight based on 100 parts by weight of the insulating resin composition, and more preferably, in a range of 10 to 900 parts by weight based on 100 parts by weight of the insulating resin composition. Further, from the viewpoint of the coating characteristic, workability, and drying time of the composition, the viscosity of the composition is preferably in a range of 5 to 5000 cps, and more preferably, in a range of 10 to 1000 cps.

A known method using a mixer, a beads mill, a pearl mill, a kneader, or three rolls is used in a method of preparing the varnish of a resin composition. All of the composition ingredients may be added at the same time, or may be added in an appropriate order. Alternatively, part of the composition ingredients may be mixed beforehand and then added, if necessary.

Coating, which is performed on the support to form a film, is performed by a general method. For example, a known coating method, such as a blade coating method, a rod coating method, a squeeze coating method, a reverse roll coating method, a transfer roll coating method, a spin coating method, a bar coating method, an air knife method, a gravure printing method, or a spray coating method, may be used to perform coating.

A method of removing a solvent is not particularly limited, but a solvent is preferably removed by the evaporation of the solvent. Examples of a method of evaporating a solvent include a heating method, a pressure reducing method, and a ventilation method. From the viewpoints of production efficiency and handleability, among the methods, evaporating the solvent by heating is preferably used, and evaporating the solvent by heating while ventilating is more preferably used. For example, a coating liquid or a varnish is preferably coated on one side of the support to be described below, and heated and dried at a temperature of 80 to 200° C. for 0.5 to 10 min to remove the solvent, thereby forming a nonsticky and semi-hardened film.

Examples of the base film that is used as the support include a resin sheet, which is formed of polyolefin, such as polyethylene, polypropylene, or polyvinyl chloride, polyester, such as polyethylene terephthalate, polyamide, polyimide, or polycarbonate, a processed paper having controlled surface adhesiveness, such as exfoliate paper, and a metal foil, such as a copper foil or an aluminum foil. The thickness of the support is generally in a range of 2 to 200 μm. The thickness of the support is preferably in a range of 5 to 50 μm, and more preferably, in a range of 10 to 30 μm. If the sheet used as the support is too thick, there is a problem in handling ability when wiring is actually formed using the laminate, specifically, when the laminate is laminated on a predetermined substrate or wiring.

Further, a mat treatment, a corona treatment, and a mold-release treatment may be performed on the surface of the sheet that forms the support. Further, a protective layer may be formed. The same material as the material of the support, or a different material from the material of the support may be used as a resin film to form a protective layer. Preferable examples of the material for the protective layer include a resin sheet, which is formed of polyolefin, such as polyethylene, polyvinyl chloride, or polypropylene, polyester, such as polyethylene terephthalate, polyamide, polyimide, or polycarbonate, a processed paper having controlled surface adhesiveness, such as exfoliate paper, and a metal foil, such as a copper foil or an aluminum foil.

The thickness of the protective layer (protective film) is generally in a range of 2 to 150 μm. Particularly, the thickness of the protective layer is preferably in a range of 5 to 70 μm, and more preferably, in a range of 10 to 50 μm. Further, one of the protective film and the support base film may be thicker than the other.

A mat treatment, embossing, and a mold-release treatment may be performed on the protective film.

If the width of the support is set to be larger than that of the insulating film or the polymer precursor layer by approximately 5 mm, it is possible to prevent a resin from being attached to a laminate portion when laminating with other layers. In addition, the support base film can be easily stripped during the use.

Laminating may be performed under reduced pressure in a batch manner, or may be performed using rolls in a continuous manner. Further, laminating may be performed on one side at one time, or may be performed on both sides at the same time. However, laminating is preferably performed on both sides at the same time. The above-mentioned laminating conditions are different depending on the thickness and the melting viscosity during heating of the composition constituting the insulating resin layer (which is solid at a normal temperature) used herein, the thickness, the diameter and the depth of a through hole of the inner layer-circuit board, and/or the diameter and the depth of a surface via hole. Preferably, the press-bonding temperature is in a range of 70 to 200° C., the press-bonding pressure is preferably in a range of 1 to 10 kgf/cm², and the laminating is performed at a reduced pressure of 20 mmHg or less. When the diameter and the depth of the through hole are large, that is, when the thickness of the board is large, the thickness of the resin composition is large and laminating conditions corresponding to high temperature and/or high pressure are required.

In general, when the thickness of the board is 1.4 mm or less and the diameter of the through hole is approximately 1 mm or less, it is possible to easily perform resin filling. Further, as the thickness of a support base film is increased, although the surface smoothness of the laminated resin composition becomes excellent, there may be a disadvantage for embedding the resin without generating voids between circuit patterns. For this reason, the thickness of the support base film is preferably in a range of +20 μm of the thickness of a conductor. However, when the surface smoothness or the thickness of the resin on the patterns are insufficient due to the large thickness of a conductor of the inner layer-circuit or dents are formed on the holes due to the large diameter and the depth of the through hole and the surface via hole, it is possible to correspond to the thicknesses of various conductors and boards by laminating the laminate for producing the multilayer printed wiring board, according to the invention thereon. After the laminating, the board is cooled to a room temperature, and the support base film is then stripped.

When the transfer is performed by laminating, the temperature is preferably in a range of 80 to 250° C., more preferably, in a range of 100 to 200° C., and still more preferably, in a range of 110 to 180° C. The pressure to be applied is preferably in a range of 0.5 to 3 Mpa, and more preferably, in a range of 0.7 to 2 Mpa. The pressure application time is preferably in a range of 10 sec. to 1 hour, and more preferably, in a range of 15 sec. to 30 min. In addition, vacuum laminating is preferably performed to improve adhesion in the laminate. Particularly, when fine wiring is formed, laminating is preferably performed in a clean room.

(2. Coating Method and Printing Method)

When the electrical insulating layer is formed by coating or printing, the coating liquid used for forming the electrical insulating layer may be repeatedly coated or printed on a surface of one side or both sides of a substrate or a circuit board having a predetermined wiring pattern, used as a base, until the coating liquid has a predetermined thickness.

Coating is performed by a general method as in the coating on the support. For example, a known coating method, such as a blade coating method, a rod coating method, a squeeze coating method, a reverse roll coating method, a transfer roll coating method, a spin coating method, a bar coating method, an air knife method, a gravure printing method, a spray coating method, or a dispensing method may be used to perform coating. Further, as the printing method, an ink jet method may be used as well as a general gravure printing method.

In addition, after the electrical insulating layer is formed on the substrate, a hardening treatment may be performed on the electrical insulating layer by applying energy. Light, heat, pressure, or electron beams may be used as the energy to be applied, but heat or light is generally used in this embodiment. Heat corresponding to a temperature of 100 to 300° C. may be applied for 10 to 120 min. Conditions of heat hardening are different depending on the type of a material of the inner layer-circuit board or the type of a resin composition constituting the laminate for forming the printed wiring board, and depend on the hardening temperature of them. More preferably, the temperature is in a range of 120 to 220° C. and the time is in a range of 20 to 120 min.

The hardening process may be performed immediately after the electrical insulating film is formed, or may be performed after the electrical insulating film is formed and various processes are then performed.

<(b) Chemically Active Spot Generating Layer>

The chemically active site generating layer used herein includes an insulating resin composition capable of being adhered to the (a) insulating layer, and a compound capable of being adhered to a (c) reactive polymer compound containing layer by generating active sites, which interact with a (c) reactive polymer compound containing layer to be described below to form chemical bond, by the following energy applying process. In particular, if the (a) insulating layer does not have polymerization initiating ability, the (b) chemically active site generating layer becomes important.

The insulating resin composition constituting the chemically active site generating layer may be different from or the same as the compounds forming the electrical insulating layer. Preferably, one or more compounds in the insulating resin compositions are the same compounds as the compounds forming the electrical insulating layer in order to improve the adhesion to the electrical insulating layer and prevent stress from being applied during the thermal history, such as an annealing treatment or a solder reflow treatment, which is performed after the layer or wiring is formed. In addition, it is preferable to use a compound having thermophysical properties, such as a glass transition point, an elastic modulus, and a coefficient of linear expansion, similar to those of the compound forming the electrical insulating layer.

The chemically active site generating layer may have the same structure as the (a) electrical insulating layer except that the chemically active site generating layer contains a compound capable of being adhered to the (c) reactive polymer compound containing layer by generating active sites, which interact with the (c) reactive polymer compound containing layer to form a chemical bond, by the energy applying process.

Any one of a thermal polymerization initiator and a photopolymerization initiator may be used as an example of the compound capable of generating active sites, which interact with a polymer compound contained in the (c) reactive polymer compound containing layer to form a chemical bond, by energy application.

The materials described above for the (a) insulating layer may be used as the examples of the compound. Further, when the (b) chemically active site generating layer can generate active sites interacting with the (c) reactive polymer compound containing layer by energy application, active species does not need to be particularly added.

A material, such as rubber, SBR, or latex, which can release stress during the heat treatment, may be added to the (b) chemically active site generating layer. Insofar as the effect of the invention is not deteriorated, depending on the purpose, the (b) chemically active site generating layer may contain various compounds, such as, a binder, a plasticizer, a surfactant, and a viscosity modifier, which are used to improve film properties, in addition to the above-mentioned compound.

The thickness of the (b) chemically active site generating layer is preferably in a range of approximately 0.1 to 10 μm, more preferably, in a range of approximately 0.3 to 7 μm, and still more preferably, in a range of approximately 0.5 to 5 μm. When in the above-mentioned thickness range, sufficient adhesion strength is obtained and interaction efficiently occurs.

A coating method, a transfer method, or a printing method can be used as a method of forming the (b) chemically active site generating layer, similar to the case of the (a) insulating layer. Further, when the (b) chemically active site generating layer is formed using the coating method, the chemically active site generating layer and the (a) insulating layer may be coated at the same time, three layers (the chemically active site generating layer, the (a) insulating layer, and the (c) reactive polymer compound containing layer) may be coated at the same time, or the layers may be sequentially formed by coating after the formation of the (a) insulating layer. Likewise, when the chemically active site generating layer is formed using the transfer method, a transfer film having a double layer structure that includes the (b) chemically active site generating layer and the (a) insulating layer, or a transfer film having a three-layer structure that includes the (c) reactive polymer compound containing layer, the (b) chemically active site generating layer, and the (a) insulating layer, may be produced on the support, and then may be transferred at one time by the laminating method. Furthermore, the solvent used to coat the (a) insulating layer may be used as a coating solvent.

Meanwhile, the viscosity of the composition that forms the (b) chemically active site generating layer is preferably within the same range as the viscosity of the composition used to form the electrical insulating layer. A general method, which has been described in the description of the formation of the electrical insulating layer, may be used as a coating method. Further, when the chemically active site generating layer is formed using the printing method, an ink jet method may also be used as well as a general gravure printing method. When the chemically active site generating layer is formed on the electrical insulating film by the printing method or the ink jet method, printing may not be performed in a region where a conductor is not to be formed, in the following process.

In addition, after the (b) chemically active site generating layer is formed, a hardening process may be performed on the chemically active site generating layer by energy application. Light, heat, pressure, electron beams or the like may be used as energy to be applied, but heat or light is generally used in this embodiment. The heat corresponding to a temperature of 100 to 300° C. may be applied for 10 to 120 min. The hardening process may be performed immediately after the (b) chemically active site generating layer is formed, or may be performed after the chemically active site generating layer is formed and various processes are then performed.

After the electrical insulating layer or the (b) chemically active site generating layer is formed, the surface may be made rough by a dry roughening method and/or a wet roughening method depending on the purpose. Examples of the dry roughening method include mechanical polishing, such as buffing, and sand blasting, and plasma etching. Meanwhile, examples of the wet roughening method include chemical treatments that use an oxidizing agent, such as permanganate, dichromate, ozone, hydrogen peroxide/sulfuric acid, or nitric acid, a strong base solvent, or a resin swelling solvent. Here, sufficient roughening does not necessarily need to be performed, and smears occurring when holes are formed at portions corresponding to through holes and/or via holes by laser and/or a drill can be only removed, which is sufficient.

<(c) Reactive Polymer Compound Containing Layer>

The (c) reactive polymer compound containing layer of the invention includes a polymer compound including a functional group to which a material used as the seed for forming the conductor layer, such as a conductive material, a precursor of the conductive material, or a plating catalyst that is used to form the (d) conductor layer, may be applied, and includes a compound including a reactive functional group capable of forming a chemical bond with the active sites generated when energy is applied to the (a) insulating layer (specifically, the (a-2) insulating layer having polymerization initiating ability) or the (b) chemically active site generating layer. Further, it is preferable to use one polymer compound, which includes a functional group to which a material used as the seed can be applied and includes a functional group capable of forming a bond. Specifically, reactive compounds, such as a compound (polymerizable compound), which is capable of generating a graft polymer by energy application, such as exposure, or a compound that is capable of forming a crosslinking structure between adjacent layers by energy application and can improve adhesion therebetween may be used as the polymer compound contained in the (c) layer. The conductive materials are preferably adhered to a polymer compound generated due to these reactive compounds. Accordingly, the reactive compound is preferably capable of causing a polymerization reaction or formation of a crosslinking structure, and further, the reactive compound preferably includes a partial structure required to be bonded to the insulating resin composition layer, for example, “radical polymerizable unsaturated double bond”, and a “functional group capable of interacting with a conductive material” that is required to adhere a conductive material to be described below to a graft polymer.

Typical examples of the reactive compounds include a polymerizable compound. The polymerizable compound is a compound that has a radical polymerizable unsaturated double bond in a molecule.

Examples of a functional group having the “radical polymerizable unsaturated double bond” include a vinyl group, a vinyl oxy group, an allyl group, an acryloyl group, a methacryloyl group, and the like. Among these groups, an acryloyl group and a methacryloyl group may exhibit high reactivity, and excellent results may be obtained.

Any compound may be used as a radical polymerizable unsaturated compound insofar as it includes a radical polymerizable group. Examples of the radical polymerizable unsaturated compound include a monomer or a macromer including an acrylate group, a methacrylate group, or a vinyl group, and an oligomer or a polymer including a polymerizable unsaturated group.

Other examples of the reactive compound include an oligomer, a polymer compound, or a combination of a crosslinking agent and a crosslinking compound. The oligomer or the polymer compound includes a reactive active group in a molecule, for example, an epoxy group, an isocyanate group, or an active group in an azo compound.

A compound having a functional group and an average molecular weight of 1000 or more is preferably used as the reactive compound. More preferably, a compound having an average molecular weight of 2000 or more is used, and still more preferably, a compound having an average molecular weight of 3000 or more is used. Further, the average molecular weight of the compound is preferably 300000 or less, more preferably, 200000 or less, and still more preferably, 150000 or less. If the (c) reactive polymer compound containing layer is formed so that the average molecular weight of the compound is in this range, dispersion of the reactive compound into the (b) chemically active site generating layer, evaporation of the reactive compound, and the like may be suppressed. Therefore, it is possible to uniformly perform exposure. In addition, the reactivity to the active sites is excellent, and the (b) chemically active site generating layer is sufficiently adhered to the (a) insulating layer.

The polymer compound partially generates chemical bond to the (b) chemically active site generating layer or the (a) insulating layer by the reactive group thereof, so that it is possible to obtain sufficient adhesion. However, as compared to a reactive polymer compound containing layer that is formed by coating a general polymerizable monomer or a crosslinking monomer, the number of bonding points between the adjacent layers is small and the motility of the reactive polymer compound is maintained to some extent. For this reason, there is an advantage that the functional group capable of applying conductive materials allows conductive materials to be efficiently adhered in large amounts.

Insofar as the effects of the invention are not deteriorated, depending on the purpose, the (c) reactive polymer compound containing layer may contain various compounds, such as, a binder, a plasticizer, a surfactant, and a viscosity modifier, which are used to improve film properties, in addition to the above-mentioned reactive compound. When the (c) reactive polymer compound containing layer is formed and energy is not yet applied, the content of the reactive compound is preferably 50% by weight or more, more preferably, 60% by weight or more, and still more preferably, 70% by weight or more. If the content of the reactive compound is 50% by weight or less, the reaction to the active sites may be deteriorated. As a result, the effects of the invention may be deteriorated.

The reactive compound needs to include a functional group that is a partial structure, to which a conductive material is adhered, and can interact with a conductive material.

A functional group, such as ammonium or phosphonium, that has positive charges, or an acid group, such as a sulfonic acid group, a carboxyl group, a phosphoric acid group, or a phosphonic acid group, that has negative charges or can be separated to have negative charges is used as the functional group capable of interacting with the conductive material. In addition, for example, a nonionic polar group, such as a hydroxyl group, an amide group, a sulfonamide group, an alkoxy group, or a cyano group may be used as the functional group capable of interacting with the conductive material.

The thickness of the (c) reactive polymer compound containing layer is preferably in a range of approximately 0.1 to 5 μm, more preferably, in a range of approximately 0.2 to 3 μm, and still more preferably, in a range of approximately 0.5 to 2 μm. If the thickness of the (c) reactive polymer compound containing layer is set in the above-mentioned range, sufficient adhesion strength is obtained and proper strength of the reactive polymer compound containing layer is obtained.

A coating method, a transfer method, or a printing method can be used as a method of forming the (c) reactive polymer compound containing layer, similar to the case of the electrical insulating layer. Further, when the (c) reactive polymer compound containing layer is formed using the coating method, the reactive polymer compound containing layer and the (b) chemically active site generating layer may be coated at the same time, three layers (the reactive polymer compound containing layer, the (a) electrical insulating layer, and the (b) chemically active site generating layer) may be coated at the same time, or the layers may be sequentially formed, and, for example, the reactive polymer compound containing layer may be formed after the coating of the (a) electrical insulating layer or the (b) chemically active site generating layer. Likewise, when the reactive polymer compound containing layer is formed using the transfer method, a transfer film having a double layer structure that includes the (c) reactive polymer compound containing layer and the (b) chemically active site generating layer, or a transfer film having a three-layer structure that includes the (c) reactive polymer compound containing layer, the (b) chemically active site generating layer, and the (a) insulating layer, may be produced on the support, and then may be transferred at one time by the laminating method.

General methods, which have been described in the description of the formation of the (a) insulating layer, may be used as a coating method.

Water or an organic solvent may be used as the solvent for coating. Specific examples of the solvent include an alcohol-based solvent, such as water, methanol, ethanol, 1-methoxy-2-propanol, or isopropanol alcohol, a ketone-based solvent, such as aceton, methyl ethyl ketone, or cyclohexanone, an ether-based solvent, such as tetrahydrofuran, ethylene glycol monomethyl ether, ethylene glycol monobutyl ether, or ethylene glycol monoethyl ether, and a nitrile-based solvent, such as acetonitrile. In addition, N-methyl-2-pyrolidone, N,N-dimethyl acetamide, N,N-dimethylformamide, ethylene glycol monomethyl ether, and tetrahydrofuran may also be used. Furthermore, for example, acetic esters, such as ethyl acetate, butyl acetate, isopropyl acetate, cellosolve acetate, propylene glycol monomethyl ether acetate, or carbitol acetate, cellosolves, such as cellosolve or butyl cellosolve, carbitols, such as carbitol or butyl carbitol, aromatic hydrocarbon, such as toluene, xylene, benzen, naphthalene, hexan, cyclohexane, dimethylformamide, dimethyl acetamide, and N-methylpyrrolidone may be used. The solvents may be used alone or two or more of the solvents may be used in combination.

Of these, a solvent that hardly dissolves the (a) electrical insulating layer or the (b) chemically active site generating layer or a solvent that hardly extracts active species from these layers are preferably combined to make the surface of the (a) electrical insulating layer or the (b) chemically active site generating layer smooth.

Further, from the viewpoint of more accurate control of the thickness, the viscosity of the coating liquid is preferably in a range of 1 to 2000 cps, more preferably, in a range of 3 to 1000 cps, and still more preferably, in a range of 5 to 700 cps.

When the layer is formed using the printing method, an ink jet method may also be used as well as a general gravure printing method. When the layer is formed on the (a) electrical insulating film or the (b) chemically active site generating layer by the printing method or the ink jet method, printing may not be performed in a region where a conductor is not to be formed, in the following process.

According to the invention, the (c) reactive polymer compound containing layer can be adhered to the (a) insulating layer or the (b) chemically active site generating layer by the interaction between the reactive polymer compound containing layer and the active sites, which are generated in the (b) chemically active site generating layer or the (a) insulating layer. Examples of the interaction include intermolecular interaction, ionic bond, chemical bond, the formation of a miscible structure. Among these, a chemical bond is preferably used since it is possible to obtain the high adhesion strength

(Energy Application)

The irradiation of an energy beam, such as light, an electromagnetic wave, an electron beam, or a radiant ray, or the application of heat energy or pressure energy is considered as a method of generating active sites in the (a) insulating layer or the (b) chemically active site generating layer. Specifically, the irradiation of an ultraviolet ray, an infrared ray, plasma, an X-ray, an alpha ray, or a gamma ray may be considered. Among them, the irradiation of an energy beam or the application of heat energy is preferably used as the method of generating active sites. Further, the irradiation of an ultraviolet ray or the like is preferable, since it is possible to apply energy using a simple device. Even though a specific active species generating compound is not added to an electrical insulating layer or an adhesion assisting layer, it is possible to generate active sites if high energy is applied to the layers by the irradiation of an ultraviolet ray, an electron beam, the plasma irradiation or the like.

Further, energy, such as light, may be applied from the side of the (c) reactive polymer compound containing layer, or from the opposite side (the side of the substrate) by energy irradiation, or by heating the entire board, such as using heat energy. However, when electrical wiring has already been formed on a lower layer and light energy is applied to the board, energy is preferably applied from the upper side of the (c) reactive polymer compound containing layer. Furthermore, when a transfer sheet where the (c) reactive polymer compound containing layer and the (a) insulating layer are laminated, a transfer sheet where the (c) reactive polymer compound containing layer and the (b) chemically active site generating layer are laminated, or a transfer sheet where the (c) reactive polymer compound containing layer, the (b) chemically active site generating layer, and the (a) insulating layer are laminated, is transferred onto a substrate or a board having a wiring, which is used as a base, to form the layers, energy may be applied after or before the transfer. When energy is applied before the transfer, energy may be applied from the side of the protective film or from the side of the support. Further, the amount of energy to be applied is properly determined so that active sites are generated and interact with the (c) reactive polymer compound containing layer interacts to form a chemical bond. In this way, the (b) chemically active site generating layer or the (a) insulating layer may be adhered to the (c) reactive polymer compound containing layer. For example, radical generators for generating active sites are added to the (b) chemically active site generating layer, and a reactive compound including a radically polymerizable unsaturated double bond and a functional group capable of interacting with the conductive material is contained in the (c) reactive polymer compound containing layer. As a result, radicals as active sites are generated on the surface of the (b) chemically active site generating layer during energy irradiation, and the reactive compound contained in the (c) reactive polymer compound containing layer generates a chemical bond as a graft.

When the energy application is achieved by the irradiation of a radiant ray, such as heat or light, heat generated by a heater or infrared rays is used to perform heating. Further, examples of the light source include a mercury lamp, a metal halide lamp, a xenon lamp, a chemical lamp, a carbon-arc lamp, and an LED. Examples of the radiant ray include an electron beam, an X-ray, an ion beam, and a far-infrared ray. Further, a g-ray, an i-ray, a Deep-UV ray, or a high-density energy beam (laser beam) may be used.

In addition, if necessary, it is possible to prevent a bond for adhesion to the (c) reactive polymer compound containing layer, the (b) chemically active site generating layer, or the electrical insulating layer from being formed by not applying energy to a region where a conductor layer is intended to be formed, for example, a region where via holes (holes) are to be formed. For example, scanning exposure, which is performed using a mask during light irradiation, may be used as a method of locally applying energy as described above.

In contrast, the (c) reactive polymer compound containing layer may be formed on the entire surface by applying energy to the entire surface, and a conductor layer may be formed on the entire surface by adhering conductive material seeds to the polymer compound.

Further, in the manufacturing method according to the invention, the (c) reactive polymer compound containing layer is adhered to the (b) chemically active site generating layer or the (a) insulating layer by energy application. Then, a process (developing process) for removing components contained in the unreacted (c) reactive polymer compound containing layer that does not contribute to the adhesion, or a composition for forming the (c) reactive polymer compound containing layer that has not been bonded to the (b) chemically active site generating layer or the (a) insulating layer may be performed.

In general, the process is performed using a solvent that can dissolve the (c) reactive polymer compound containing layer and does not dissolve the (a) insulating layer or the (b) chemically active site generating layer. Specifically, water, an alkaline developer, an organic solvent-based developer, or the like is used to perform the process. A method where an object is immersed in the solvent and the solvent is stirred, or a pressure cleaning method, such as shower, is often used as the developing method.

In addition, after the (c) reactive polymer compound containing layer is formed and adhered to the (b) chemically active site generating layer or the (a) insulating layer by the energy irradiation, extra (c) reactive polymer compound containing layer is removed by the above-mentioned method. Further, a plasma treatment, an ultraviolet treatment and the like may be used to improve the adhesion between the (c) reactive polymer compound containing layer and a seed compound.

The method according to the invention may include a hole forming process for forming a hole, which is required to form a multilayer wiring board. In this case, the hole is used to connect a conductor layer to be formed to the wiring formed on the lower layer, the wiring formed on the substrate, or the wiring formed on the opposite side of the substrate. Drilling is generally performed as the hole forming process, but laser machining may also be performed for forming fine via holes (holes).

Laser, which has an oscillation wavelength between an ultraviolet range and an infrared range, may be used in the hole forming process. In this case, the ultraviolet range corresponds to a wavelength in a range of 50 to 400 nm, and the infrared range corresponds to a wavelength in a range of 750 nm to 1 mm. Examples of available laser include ultraviolet laser and carbon dioxide gas laser.

The emission wavelength of ultraviolet laser is generally in a range of 180 to 380 nm, the emission wavelength of ultraviolet laser is preferably in a range of 200 to 380 nm, and more preferably, in a range of 300 to 380 nm. Examples of the laser that is used to obtain ultraviolet laser include gas laser, such as Ar laser, N₂ laser, ArF laser, KrF laser, XeCl laser, XeF laser, He—Cd laser, and He—Ne laser; solid laser, such as YAG laser, NdYAG laser, Nd glass laser, and alexandrite laser; and dye laser using dye dissolved in an organic solvent.

In the case of YAG laser or NdYAG laser, high output energy oscillation can be achieved, and a laser device has a long life span and can be maintained at low cost. For this reason, YAG laser or NdYAG laser is particularly preferable. A harmonic wave of the laser is suitably used as an oscillation wave corresponding to an ultraviolet range. The laser harmonic wave can be obtained as follows: a laser beam (fundamental wave) having a wavelength of 1.06 μm is oscillated with, for example, YAG laser. Then, the laser beam passes through two nonlinear crystals (LBO crystals) that stand in line with a predetermined distance therebetween in a direction of a light path, so that the laser beam is converted into SHG light having a wavelength of 0.53 μm and subsequently converted into THG light (ultraviolet ray) having a wavelength of 0.355 μm. Examples of a device, which is used to obtain the harmonic wave, include a laser beam machine disclosed in JP-A No. 11-342485, and the like.

The laser can be irradiated continuously or intermittently. However, if the laser is intermittently irradiated as a single pulse, it is possible to prevent cracks from occurring. For this reason, the laser is preferably intermittently irradiated as a single pulse. The number of single pulse irradiation (shot number) is generally in a range of 5 to 100 times, and preferably, in a range of 10 to 50 times. If the number of irradiation is increased, machining time is increased. Accordingly, cracks tend to easily occur. A pulse period is generally in a range of 3 to 8 kHz, and preferably, in a range of 4 to 5 kHz. Carbon dioxide gas laser is molecule laser. In the case of carbon dioxide gas laser, an efficiency of converting electric power into a laser beam is 10% or more, and at an oscillation wavelength of 10.6 μm, large output corresponding to tens of kW can be generated. In general, carbon dioxide gas laser has energy in a range of approximately 20 to 40 mJ, and is irradiated as a short pulse corresponding to approximately 10⁻⁴ to 10⁻⁸ sec.

The shot number of a pulse, which is required to form via holes, is generally in a range of approximately 5 to 100 shots. The holes to be formed are used as through holes and blind via holes.

A ratio of an inner diameter (d1) of a bottom of a hole to an inner diameter (d0) of an inlet (surface) portion of a hole (hole diameter ratio: d1/d0×100[%]) is generally 40% or more, a hole diameter ratio is preferably 50% or more, and more preferably, 65% or more. Further, d0 is preferably in a range of 10 to 250 μm, and more preferably, in a range of 20 to 80 μm. If the hole diameter ratio is large, defective continuity hardly occurs between insulating layers and a multilayer circuit board has high reliability.

The hole forming process of the invention may be performed after the (a) insulating layer is formed, after the (b) chemically active site generating layer is formed, after the (c) reactive polymer compound containing layer is formed, after a seed layer to be described below is formed, or after the conductor layer is formed.

When the hole forming process is performed after the (a) insulating layer is formed, it is possible to apply seeds to the holes and to easily form a (d) conductor layer (to be described below) to the holes by transferring or coating the (b) chemically active site generating layer and the (c) reactive polymer compound containing layer to the holes during the following process. Meanwhile, when the hole forming process is performed after the (b) chemically active site generating layer is formed, after the (c) reactive polymer compound containing layer is formed, after a seed layer to be described below is formed, or after the (d) metal conductor layer is formed, a conductor film is formed at the holes by separate plating. Accordingly, a general conditioning treatment or a catalyst applying treatment needs to be performed.

In addition, after the hole forming process, a desmear process for removing smears remaining at the holes may be performed. The desmear process is performed by roughening the surfaces of the via holes in a dry or wet manner depending on the purpose.

Examples of a dry roughening method include mechanical polishing, such as buffing and sand blast, or plasma etching. Meanwhile, examples of the wet roughening method include chemical treatments in which an oxidizing agent, such as permanganate, dichromate, ozone, hydrogen peroxide/sulfuric acid, or nitric acid, a strong base, or a resin swelling solvent is used.

The desmear process may be performed after electroless plating is performed on the insulating film using seeds to form a metal film used as a power feed layer. The desmear process includes a swelling process, an etching process, and a neutralizing process. For example, a representative example of the desmear process is embodied by sequentially performing a swelling process that is performed at 60° C. for 5 minutes using an organic solvent-based swelling solution, an etching process that is performed at 80° C. for 10 minutes using a sodium permanganate-based etchant, and a neutralizing process that is performed at 40° C. for 5 minutes using a sulfuric acid-based neutralizing solution.

According to the invention, even though the surfaces of the substrate or the insulating layer are not roughened, it is possible to obtain a sufficient adhesion force between metal (conductor layer) and an organic substrate. For this reason, if the desmear process is performed after the conductor layer is formed, for example, after electroless plating, it is possible to form a metal film on the smooth surface of a substrate and to satisfactorily remove smears of the via holes. Therefore, the desmear process is preferably performed after the conductor layer is formed.

Here, sufficient roughening does not necessarily need to be performed, and smears occurring when holes are formed at portions corresponding to through holes and/or via holes using laser and/or a drill can be only removed, which is sufficient.

<Formation of (d) Conductor Layer>

A (d) conductor layer formed of a conductive material can be formed as follows: seeds (materials as a base material capable of forming a conductor layer, such as a conductive material or a precursor thereof), which is a pretreatment for applying a conductive material, are applied to the functional group of the polymer compound contained in the (c) reactive polymer compound containing layer. Then, a method of converting the seeds into a conductor layer, or a method of performing electroless plating or electroplating while the seeds are used as a base material is performed, thereby forming a conductor layer.

For example, a method where ions formed of metal capable of interacting with a functional group that is capable of interacting with the conductive material and is contained in the (c) reactive polymer compound containing layer are reduced and electroless plating is then performed while using the metal as a plating catalyst, a method using a directly reduced metal film, and a method of allowing a metal colloid or metal nanoparticles to interact with conductive particles have been known as a method of applying seeds to the (c) reactive polymer compound containing layer of the invention.

Specifically, a (1) method of allowing metal ions to be adsorbed to a graft polymer formed of a compound including a polar group (ionizable group) that is a functional group capable of interacting with a conductive material, or a (2) method of impregnating metal salt or a solution containing metal salt into a graft polymer formed of a nitrogen-containing or sulfur-containing polymer, such as, polyvinyl pyrolidone, polyvinyl pyridine, or polyvinyl imidazole, which has high compatibility with the metal salt, may be used as a method of performing the process for applying metal ions or metal salt and then reducing the metal ions or metal ions contained in metal salt in order to deposit metal. A method that includes forming the (c) reactive polymer compound containing layer that includes a functional group interacting with an electroless plating catalyst or a precursor thereof, applying an electroless plating catalyst or a precursor thereof to the (c) reactive polymer compound containing layer, and performing electroless plating to form a metal thin film may be used as a (3) method of applying an electroless plating catalyst or a precursor thereof to the (c) reactive polymer compound containing layer adhered to the (b) chemically active site generating layer and then performing electroless plating.

The conductive particles are not particularly limited insofar as they have conductivity. Any particles formed of a known conductive material can be arbitrarily and selectively used. Preferable examples of conductive particles include metal particles, such as Au, Ag, Pt, Cu, Rh, Pd, Al and Cr; oxide semiconductor particles, such as In₂O₃, SnO₂, ZnO, CdO, TiO₂, CdIn₂O₄, Cd₂SnO₂, Zn₂SnO₄ and In₂O₃—ZnO; particles obtained by doping the impurities which can be applied thereto; spinel type compound particles, such as MgInO and CaGaO; conductive nitride particles, such as TiN, ZrN and HfN; conductive boride particles, such as LaB; and conductive polymer particles as organic materials. The diameter of the conductive particles is preferably in a range of 0.1 to 1000 nm, and more preferably, in a range of 1 to 100 nm. If the diameter of the conductive particles is smaller than 0.1 nm, conductivity that is generated by continuous contact of the particles tends to be decreased. If the diameter of the conductive particles is larger than 1000 nm, a contact area of the particles interacting with the functional group of which polarity is converted is decreased. For this reason, the strength of the conductive region tends to be deteriorated. Further, if the diameter exceeds 1000 nm, a contact area that interacts with and is bonded to a functional group decreases. For this reason, the adhesiveness to particles tends to be deteriorated.

In this process, the metal salt is not particularly limited insofar as it can be dissolved in a suitable solvent for applying to the graft polymer generation region and is divided into a metal ion and a base (negative ion). Examples of the metal salt include M(NO₃)ₙ, MClₙ, M_{2/n}(SO₄), M_{3/n}(PO₄) (where M represents an n-valent metal atom). The metal ion obtained by dissociating the above metal salt can be suitably used. Specific examples of the metal ion include Ag, Cu, Al, Ni, Co, Fe, and Pd. Ag is preferably used for the conductive film, and Co is preferably used for the magnetic film.

The electroless plating catalyst used in this process is mainly a zero valence metal. Examples of the electroless plating catalyst include Pd, Ag, Cu, Ni, Al, Fe, and Co. Particularly, Pd and Ag are preferably used in view of excellent handleability and high catalyst power. For example, a technique for applying metal colloid, in which an electric charge is adjusted so as to interact with the interactive group in the interaction region, to the interaction region is used as a technique for fixing the zero valence metal to the interaction region. Generally, the metal colloid can be produced by reducing the metal ion in a solution in which a surface-active agent having electric charge or a protecting agent having electric charge exists. The electric charge of the metal colloid can be adjusted by the surface-active agent or protecting agent used herein. Accordingly, the metal colloid (electroless plating catalyst) can be adhered to the (c) reactive polymer compound containing layer by interacting the metal colloid in which the electric charge is adjusted with the interactive group (polar group) in the (c) reactive polymer compound containing layer.

The electroless plating catalyst precursor used in this process is not particularly limited insofar as it can become an electroless plating catalyst by a chemical reaction. The metal ion of the zero valence metal in the above electroless plating catalyst is mainly used. The metal salt to be used is not particularly limited insofar as it can be dissociated into a metal ion and a base (negative ion). Examples of the metal salt include M(NO₃), MClₙ, M_{2/n}(SO₄), M_{3/n}(PO₄) (where M represents an n-valent metal atom). A metal ion obtained by dissociating the above metal salt can suitably be used. Specific examples of the metal ion include an Ag ion, a Cu ion, an Al ion, a nickel ion, a Co ion, a Fe ion, and a Pd ion. Particularly, the Ag ion and the Pd ion are preferably used in view of catalyst power.

A metal ion, which is a precursor of an electroless plating catalyst, is converted into a zero valence metal, which is an electroless plating catalyst, by a reductive reaction. A metal ion, which is a precursor of an electroless plating catalyst, may be converted into a zero valence metal by a separate reductive reaction after being applied to a board but before being immersed in an electroless plating bath, thereby being used as an electroless plating catalyst. Alternatively, a precursor of an electroless plating catalyst may be directly immersed in an electroless plating bath so as to be converted into metal (electroless plating catalyst) due to a reducing agent contained in the electroless plating bath.

Here, the metal salt is dissolved in a suitable solvent. Then, the solution containing dissociated metal ions may be coated on the (c) reactive polymer compound containing layer, or a substrate, in which the (c) reactive polymer compound containing layer has been formed, may then be immersed in the solution in order to apply conductive particles, a metal ion, metal salt, an electroless plating catalyst, and a precursor of the electroless plating catalyst. If the functional group comes in contact with the solution containing metal ions, metal ions may be adsorbed to the functional group.

From the viewpoint of sufficiently performing the adsorption, the metal ions concentration of the above-mentioned solution or the metal salt concentration is preferably in a range of 0.01 to 50% by mass, and more preferably, in a range of 0.1 to 30% by mass. Further, the contact time is preferably in a range of approximately 10 sec. to 24 hours, and more preferably, in a range of approximately 1 to 180 min.

According to the invention, for example, a substrate is immersed in a plating catalyst liquid (for example, aqueous solution of silver nitrate or a tin-palladium colloidal solution) to apply a plating catalyst to the (c) reactive polymer compound containing layer fixed on the electrical insulating layer. Examples of an electroless plating catalyst include fine metal powder, such as palladium, gold, platinum, silver, copper, nickel, cobalt, and tin, and/or halogenated compounds thereof, oxide thereof, hydroxide thereof, sulfide thereof, peroxide thereof, amine salt thereof, sulfate thereof, nitrate thereof, organic acid salt thereof, and an organic chelate compound thereof. Further, the examples of an electroless plating catalyst may include materials that are obtained by allowing the above-mentioned materials to be adsorbed in various inorganic components. In this case, known materials, such as colloidal silica, calcium carbonate, magnesium carbonate, magnesium oxide, barium sulfate, barium titanate, silicon oxide, amorphous silica, talc, clay, and mica may be used as the inorganic components. Any material may be used as the inorganic component Insofar as it is fine powder, such as alumina or carbon. The mean particle size of the fine powder is preferably in a range of 0.1 to 50 μm.

The conductive particles or the metal ion, the metal salt, the electroless plating catalyst, and the precursor of the electroless plating catalyst may be used alone, or two or more of them may be used in combination, if necessary. Further, a mixture obtained by mixing the above-mentioned materials beforehand may be used to obtain desired conductivity.

Furthermore, after the substrate is immersed in the plating catalyst liquid, an extra plating catalyst liquid is removed by washing.

The reducing agent used to reduce metal ions or metal salt adsorbed or impregnated into the (c) reactive polymer compound containing layer and form a metal (fine particles) film in this process is not particularly limited insofar as it has a physical property for reducing a used metal salt compound to deposit a metal. Examples of the reducing agent include hypophosphite, tetrahydroborate, and hydrazine.

The reducing agent may be properly selected in consideration of a relationship with used metal salt and metal ions. For example, when an aqueous solution of silver nitrate is used as an aqueous solution of metal salt for supplying metal ions or metal salt, sodium tetrahydroborate is preferably used as the reducing agent. When an aqueous solution of palladium dichloride is used as an aqueous solution of metal salt for supplying metal ions or metal salt, hydrazine is preferably used as the reducing agent. Examples of the method of adding the reducing agent include a method that includes applying metal ions or metal salt onto the surface of the electrical insulating layer including the (c) reactive polymer compound containing layer; washing the surface with water so as to remove extra metal salt and metal ions; and immersing an electrical insulating layer, which includes an adhesion assisting layer having the surface, in ion-exchange water to add the reducing agent to the electrical insulating layer; and a method of directly coating or dropping an aqueous solution of a reducing agent, which has a predetermined concentration, onto the surface of the electrical insulating layer including the adhesion assisting layer. Meanwhile, it is preferable to use the excess amount of the added reducing agent, which is equal to or larger than equivalence, with respect to metal ions. It is more preferable to use 10 times equivalent of the added reducing agent.

If the seed layer applied to the adhesion assisting layer has sufficient conductivity, a conductor layer may be formed by performing electroplating as it is. However, sufficient conductivity may not be obtained only by applying metal ions or an electroless plating catalyst. Accordingly, electroless plating is further performed using an electroless plating catalyst in this case.

The electroless plating means an operation to deposit the metal by the chemical reaction using a solution, in which the metal ion to be deposited as plating is dissolved. The electroless plating may be performed after soft etching and acid cleaning. Further, the electroless plating may be performed by a process using an activator or an accelerator, which are generally available to the market.

In the electroless plating of this process, for example, the substrate to which the electroless plating catalyst obtained in this process for applying the electroless plating catalyst is applied is washed, and the excessive electroless plating catalyst (metal) is removed. Then, the substrate is immersed in the electroless plating bath. A generally known electroless plating bath can be used as the electroless plating bath.

When the substrate to which the electroless plating catalyst precursor is applied is immersed in the electroless plating bath in a state where the electroless plating catalyst precursor is adhered to the (c) reactive polymer compound containing layer, or is impregnated therewith, the substrate is immersed in the electroless plating bath after the substrate is washed and the excessive precursor is removed (metal salt or the like). In this case, the precursor is reduced in the electroless plating bath, and the electroless plating is then performed. Similarly, a generally known electroless plating bath can be used as the electroless plating bath to be used in this process.

Meanwhile, the precursor of the electroless plating catalyst is reduced to form an electroless plating catalyst, and may be immersed in an electroless plating bath. In this case, the extra precursor of the electroless plating catalyst is removed by cleaning.

As the composition of the general electroless plating bath, (1) the metal ion for plating, (2) the reducing agent and (3) the additive agent (stabilizer) for enhancing the stability of the metal ion are mainly contained. In addition to the materials, known additives, such as the stabilizer of the plating bath, may be contained in the plating bath.

Examples of the metal used for the electroless plating bath include silver, chromium, copper, tin, lead, nickel, gold, palladium, and rhodium. Of these, silver, copper, gold, chromium, and nickel are preferably used from the viewpoint of conductivity.

The reducing agents and the additives that can be suitably used together with the above metals will be described. For example, a copper electroless plating bath contains Cu(SO₄)₂ as copper salt, HCOH as the reducing agent, and a chelating agent, such as EDTA and roshell salt, which is the stabilizer of copper ion as an additive agent. A CoNiP electroless plating bath contains cobalt sulfate and nickel sulfate as the metal salt; sodium hypophosphite as the reducing agent; and sodium malonate, sodium malate, and sodium succinic acid as a complexing agent. The palladium electroless plating bath contains (Pd(NH₃)₄)Cl₂ as the metal ion, NH₃, H₂NNH₂ as the reducing agent, and EDTA as a stabilizing agent. Ingredients other than the above components may be contained in the plating baths.

Although the thickness of the conductive film (metal film) formed as described above can be controlled by the concentration of the metal salt or the metal ion of the plating bath, the immersion time to the plating bath, or the temperature of the plating bath, the thickness is preferably 0.1 μm or more from the viewpoint of conductivity, and more preferably 3 μm or more. The immersion time to the plating bath is preferably in a range of approximately 1 minute to 3 hours, and more preferably, in a range of approximately 1 minute to 1 hour.

Chromium or nickel plating is performed as electroless plating in order to improve the adhesion to the resin forming the electrical insulating layer, and copper plating is performed as electroplating that is performed to form the conductor layer. As described above, metal formed by electroless plating may be different from metal formed by electroplating.

Further, when a copper clad plate used in subtractive method is formed, an electroplating process may be performed to form a conductor layer later.

Electroplating may be further performed during an electroplating process after the electroless plating of the electroless plating process, while the metal film (conductive film) formed by the electroless plating process is used as an electrode. Accordingly, a metal film having a predetermined thickness can be easily formed on the substrate using the metal film that has excellent adhesiveness to the insulating resin layer as a base material. The thickness of the metal film corresponding to the purpose can be formed by adding the process. The conductive material obtained by this embodiment is suitably applied to various applications.

As the electroplating method of this embodiment, known methods can be used. Examples of the metal for electroplating in this process include copper, chromium, lead, nickel, gold, silver, tin, and zinc. Of these, copper, gold, and silver are preferably used from the viewpoint of conductivity. Particularly, copper is used. The thickness of the metal film obtained by electroplating varies according to the applications, and the thickness can be controlled by adjusting the metal concentration, the immersion time, or the current density in the plating bath. The thickness when a general electric wiring is used is preferably 0.3 μm or more, and more preferably 3 μm or more from the viewpoint of conductivity. For example, the electroplating process used herein can be performed to mount an IC as well as to form the patterned metal film having the thickness according to the purpose as described above. The plating for this purpose can be performed to the conductive film and the metal pattern surface formed of copper or the like using a material selected from the group consisting of nickel, palladium, gold, silver, tin, solder, rhodium, platinum, and a compound thereof.

The subtractive method is as follows. (1) A resist layer is formed by coating on the metal film that is formed by the electroplating in the above-mentioned method. (2) The resist pattern of a conductor that should remain is formed by pattern exposure and development. (3) The unnecessary metal film is removed by etching. (4) The resist layer is stripped, and a metal pattern is formed. The thickness of the metal film in this embodiment is preferably 5 μm or more, and more preferably in a range of 5 to 30 μm.

In this case, a process of connecting to wiring that is formed on a lower layer or a substrate as a base material, or wiring that is formed on the opposite side using the via holes may be performed. When the via holes are formed after the electrical insulating layer is formed, and when the (b) chemically active site generating layer and the (c) reactive polymer compound containing layer are formed in a subsequent process, it is possible to also plate the via holes in the electroless plating process at the same time. Meanwhile, if the via holes are formed after the (b) chemically active site generating layer, the (c) reactive polymer compound containing layer, and the conductive layer are formed, it is possible to achieve the connection by performing additional electroless plating at only holes in such a manner that the through holes are plated with a known copper clad plate. Further, the via holes may be completely plated with a plating metal using electroplating in combination. Furthermore, another example of a connection method may include a method of filling holes with conductive particles, metal nanoparticles, metal nanopaste, an conductive adhesive or the like, which contain a metal element, such as copper, silver, or gold, using a printing method, a dispensing method, or an ink jet method so as to achieve the connection.

In addition, after the conductor layer is formed, a heat treatment may be performed. The heating temperature during the heat treatment is preferably 100° C. or more, more preferably, 130° C. or more, and still more preferably, approximately 180° C. In view of treatment efficiency or dimensional stability of the electrical insulating layer, the heating temperature is preferably 400° C. or less. Meanwhile, the heating time is preferably 10 minutes or more, and more preferably, in a range of approximately 30 to 120 minutes. Accordingly, the hardening of a thermosetting resin is progressed, so that it is possible to further improve the peel strength of a conductor layer.

In addition, it is possible to perform a process for forming a plating resist on the conductor layer by a semi-additive method to form wiring patterns. The semi-additive method is a method of forming metal patterns that includes (1) coating a resist layer on a metal film formed on the (c) reactive polymer compound containing layer, (2) forming resist patterns of a conductor to be removed by pattern exposure and development, (3) forming a metal film on non-patterned portions of the resist by plating, (4) stripping a DFR, and (5) removing an unnecessary metal film by etching. The semi-additive method is a method of forming a conductor layer on a portion not having a resist by electroplating while using a first formed metal film as a power feed layer. The above-mentioned electroless plating or electroplating may be used as a plating method. Further, the metal film, on which the resist layer is coated, preferably has a thickness in a range of approximately 0.3 to 3 μm to complete the etching process in a short time. In addition, electrolytic plating or electroless plating may be performed on the formed metal patterns.

(1) Resist Layer Forming Process

Resist

As photosensitive resist to be used, a photosetting negative resist or a photofusing positive resist that is dissolved by exposure can be used. Examples of the photosensitive resist include (1) a photosensitive dry film resist (DFR), (2) a liquefied resist, and (3) an ED (electrodeposition) resist. These have the following characteristics. (1) The photosensitivity dry film resist (DFR) can be simply treated since it can be used in a dry method. (2) The liquefied resist film has a thin thickness as the resist, and thus a pattern having sufficient resolution can be produced using the same. (3) The ED (electrodeposition) resist has a small thickness as the resist, and thus a pattern having sufficient resolution can be produced using the same. Also, the following of the irregularities of the coating surface is excellent, and thus excellent adhesiveness can be obtained. The resist to be used may be suitably selected according to the features.

Coating Method

1. Photosensitive Dry Film

A photosensitive dry film generally has a sandwich structure, which is interposed between a polyester film and a polyethylene film, and is press-bonded by a hot calendar roll while the polyethylene film is stripped by a laminator.

A prescription of a photosensitive dry film resist, a method of forming a photosensitive dry film resist, and a method of laminating a photosensitive dry film resist have been described in detail in the paragraphs [0192] to [0372] in the specification of Japanese Patent Application No. 2005-103677, and it can be applied to the invention.

2. Liquid Resist

A spray coating method, a roll coating method, a curtain coating method, a deep coating, or a dip coating method is used as a coating method. The roll coating method or the dip coating method is preferably used to coat both surfaces at the same time.

A liquid resist has been described in detail in the paragraphs [0199] to [0219] in the specification of Japanese Patent Application No. 2005-188722, and it can be applied to the invention by reference.

3. ED (electrodeposition) Resist

The ED resist is colloids obtained by suspending particles formed of photosensitive resist in water. Since the particles are charged, when a voltage is applied to the conductor layer, the resist is deposited on the conductor layer by electrophoresis. The colloids are mutually connected on the conductor to be in a film state and can be coated.

(2) Pattern Exposure Process

“Exposure”

A substrate in which the resist film is provided on the upper portion of the metal film is stuck with a mask film or a dry plate, and exposed with light of the irradiated region of the used resist. When the film is used, the substrate is stuck by a vacuous baking flame and exposed. An exposure source for a pattern width of approximately 100 μm may be a point light source. When pattern width having 100 μm or less is formed, it is preferable to use a parallel light source. Further, in recent years, there has been proposed a method for forming patterns by digital exposure that is performed using laser without using a mask film or a dry plate.

“Development”

Any developer may be used insofar as it can dissolve an unexposed portion when the photosetting negative resist is used, or dissolve an exposed portion when the photofusing positive resist which can be dissolved by light is used. An organic solvent and an alkaline solution are mainly used as the developer. In recent years, an alkaline solution is used in view of environmental impact reduction.

(3) Forming Metal Film on Non-Patterned Portions of Resist by Plating

Electroplating may be further performed after the patterns is formed, while a metal film or a conductive film (for example, a film formed by electroless plating) disposed below the patterns is used as a power feed electrode. Accordingly, it is possible to newly form a different metal film having a predetermined thickness, using the metal film that has excellent adhesiveness to the electrical insulating layer as a base material. Due to the addition of this process, it is possible to form a metal film that has a thickness corresponding to the purpose, and to apply the conductive material, which is obtained from this embodiment, to various applications.

Known methods in the related art may be used as the electroplating method of this embodiment. Meanwhile, examples of the metal, which is used in the electroplating of this process, may include copper, chromium, lead, nickel, gold, silver, tin, and zinc. From the viewpoint of conductivity, copper, gold, or silver is preferably used for electroplating. Specifically, copper is more preferable.

Further, if the resist is thick, the conductor layer to be formed by electroplating becomes thick. If the resist is thin, the conductor layer to be formed by electroplating becomes thin. If the conductor layer to be formed by electroplating is thicker than the resist, it is difficult to strip the resist and a space between adjacent lines becomes small, and therefore, it is not preferable.

(4) Resist Stripping Process

“Stripping Process”

Since the plating resist is unnecessary after the metal (conductivity) pattern is completely formed by electroplating, a process of stripping an plating resist is needed. The plating resist can be stripped by spraying a stripping solution. Although the stripping solution is different according to the kind of the resist, in general, a solvent or a solution for swelling the resist is sprayed by a spray, such that the resist is swelled and stripped.

(5) Etching Process

“Etching”

Etching is performed to chemically dissolve and remove the power feed layer that becomes unnecessary, and thereby imparting an insulation property between conductor patterns to complete the conductor patterns. In the etching process, an etchant is mainly sprayed from the upper and lower sides on a horizontal conveyor. As the etchant, an oxidizing aqueous solution that dissolves and oxidizes a metal layer may be used. Examples of the etchant include a ferric chloride liquid, a cupric chloride liquid, and an alkali etchant. Since the resist may be stripped by alkali, a ferric chloride liquid or a cupric chloride liquid is mainly used.

The surface of the substrate is not made uneven in the method according to the invention. Accordingly, removal characteristic of conductive components is excellent in the vicinity of the interface of the substrate, and the (c) reactive polymer compound containing layer by which a metal film is introduced on a substrate is bonded to the (b) chemically active site generating layer or the electrical insulating layer at a terminal of a polymer chain. For this reason, the (c) reactive polymer compound containing layer has a structure having very high motility. Accordingly, the etchant can be easily diffused into a graft polymer layer in the etching process, and removal characteristic of metal components is excellent on the interface between the substrate and the metal layer. As a result, it is possible to form patterns excellent in sharpness.

According to the invention, after the wiring patterns are formed, a process for passivating the (c) reactive polymer compound containing layer remaining on portions not having wiring may be performed. Since it is possible to easily remove seeds by the passivation, it is possible to prevent failure, such as ionic migration, from occurring. Examples of the passivating process may include a process for forming an insoluble salt by allowing the (c) reactive polymer compound containing layer to interact with a certain type of ionic compound, and a method of chemically modifying properties of a functional group, which is capable of interacting with a plating catalyst, thereby changing the functional group to a different insulating group. Further, in order to improve the adhesion to an electrical insulating layer or a solder resist layer that is formed on an upper layer, the modification may be performed so as to obtain a functional group that can be chemically bonded to these layers.

After wiring patterns are formed, a process for removing the (c) reactive polymer compound containing layer remaining on portions not having wiring may be performed. Examples of the removing process may include a desmear process used for a roughening treatment. A desmear process using an alkaline permanganic acid has been known. The desmear process may be performed after electroless plating is performed on the insulating film using seeds to form a metal film used as a power feed layer. The desmear process includes a swelling process, an etching process, and a neutralizing process. It is possible to improve the adhesion to an electrical insulating layer or a solder resist layer, which is formed on an upper layer, by performing this process. Since surface has not been roughened when wiring is formed, it is possible to form wiring patterns having high definition.

Meanwhile, a copper surface treatment may be performed on the formed conductor pattern. A black oxidizing method, a copper oxide reducing method, a copper surface roughening method, a surface roughening electroless copper plating method, or the like may be used as a method of performing the above-mentioned treatment. It is possible to improve the adhesion to an electrical insulating layer or a solder resist layer, which is formed on an upper layer, by performing the above-mentioned methods. In addition, an antirust treatment may also be performed to prevent metal conductors from being oxidized.

By returning to the process for forming the electrical insulating layer after the patterns are formed, it is possible to form a multilayer board. A process for forming a protective layer, a process for forming a solder resist film, and a finishing plating (for example, nickel-gold plating, solder coating, or the like) may be performed on the outermost layer, so that it is possible to manufacture a board.

As described above, it is possible to easily form a printed wiring board having excellent characteristics, on which fine wiring patterns can be formed, by the method of producing the multilayer printed wiring board according to the invention. If the conductive material, such as a copper clad laminated plate, which is obtained by the manufacturing method according to the invention, is used, it is possible to form copper wiring having fine patterns of 20 micron or less and high adhesive strength, which was difficult in the related art, by, for example, a known etching treatment. Since the printed wiring board obtained by the invention has excellent surface smoothness, it is possible to manufacture a multilayer printed wiring board by repeating the above-mentioned manufacturing method several times and laminating buildup layers as a multilayer structure.

Surface roughening is not necessarily required for the method of manufacturing the printed wiring board according to the invention and the printed wiring board produced using the method. Therefore, it is possible to form fine wiring patterns and the method is useful to form a multilayer printed wiring board having high adhesion strength.

### EXAMPLES

The present invention will be described in detail below with reference to specific examples, but is not limited to the specific examples. The term “parts” used herein represents “parts by mass” unless specifically mentioned.

### Example 1

Chemical polishing was performed on the surface of a glass epoxy board (patterned glass epoxy inner layer-circuit board (thickness of a conductor: 18 μm)) on which wiring patterns were formed. Then, an epoxy-based insulating film (trade name: GX-13, manufactured by Ajinomoto Fine-Techno Co. Inc., thickness: 45 μm) used as an electrical insulating layer was heated, pressed and adhered on the glass epoxy board at a pressure of 0.2 Mpa and a temperature of 100 to 110° C. by a vacuum laminator, thereby forming an (a) electrical insulating layer. Further, an insulating composition having the following composition, which was used as a coating liquid composition for forming a (b) chemically active site generating layer, was coated on the (a) insulating layer by a spin coating method so as to have a thickness of 3 microns. Then, the insulating composition was dried at 140° C. for 30 minutes, thereby forming a (b) chemically active site generating layer.

(Formation of (b) Chemically Active Spot Generating Layer Containing Initiator)

20 parts by mass of a bisphenol A epoxy resin (epoxy equivalent 185, trade name: EPIKOTE 828, manufactured by Yuka Shell Epoxy Co., Ltd.) (hereinafter, the blending amount was described by parts by mass), 45 parts of a cresol novolac epoxy resin (epoxy equivalent 215, trade name: EPICLON N-673, manufactured by Dainippon Ink And Chemicals Inc.), and 30 parts of a phenol novolac resin (phenolic hydroxyl group equivalent 105, trade name: PHENOLITE, manufactured by Dainippon Ink And Chemicals Inc.) were dissolved with heating in 20 parts of ethyldiglycol acetate and 20 parts of solvent naphtha 20 while stirring. Then, the mixture was cooled to a room temperature. Subsequently, 30 parts of cyclohexanone varnish (trade name: YL6747H30, manufactured by Yuka Shell Epoxy Co., Ltd., nonvolatile ingredient 30% by mass, and weight average molecular weight 47000) of a phenoxy resin formed of the EPIKOTE 828 and the bisphenol S, 0.8 parts of 2-phenyl-4,5-bis(hydroxymethyl)imidazole, 2 parts of fine grinding silica, and 0.5 parts of a silicon-based anti-foaming agent were added to the mixture. In addition, 10 parts of a polymerization initiating polymer P, which was synthesized by the following method, was added to the mixture, thereby producing a coating liquid for forming a (b) chemically active site generating layer.

(Synthesis of Polymerization Initiating Polymer P)

30 g of propylene glycol monomethyl ether (MFG) was added to the mixture in a 300 mL three-necked flask, and then the mixture was heated to 75° C. A solution, which was formed of 8.1 g of [2-(acryloyloxy)ethyl] (4-benzoylbenzyl)dimethyl ammonium bromide, 9.9 g of 2-hydroxyethylmethaacrylate 9.9 g, 13.5 g of isopropylmethaacrylate, 0.43 g of dimethyl-2,2′-azobis(2-methyl propionate), and 30 g of MFQ was dropped into the flask for 2.5 hours. Subsequently, a reaction temperature was increased to 80° C. and a reaction was further performed for 2 hours, thereby obtaining a polymer P including a polymerization initiating group.

Further, after the electrical insulating layer and the (b) chemically active site generating layer are formed, a hardening treatment was performed at 180° C. for 30 minutes.

Then, a liquid having the following composition was prepared as a for forming a (c) reactive polymer compound containing layer, and was coated on the (b) chemically active site generating layer by a spin coating method so as to have a thickness of 1.5 microns. Then, the solution was dried at a temperature of 80 to 120° C., thereby forming a (c) reactive polymer compound containing layer.

(Liquid Composition 2 for Forming (C) Reactive Polymer Compound Containing Layer)

| | | |
|---|---|---|
| Polymer including a polymerizable group | 3.1 | g |
| on a side chain (P-1) | | |
| Water | 24.6 | g |
| 1-methoxy-2-propanol | 12.3 | g |

(Synthesis Example: Synthesis of Polymer P-1 Having Double Bond)

60 g of polyacrylic acid (average molecular weight 25000, Wako Pure Chemical Industries, Ltd.) and 1.38 g of hydroquinone (Wako Pure Chemical Industries, Ltd.) were put in a 1 L three-necked flask, which was provided with a cooling pipe. Then, 700 g of N,N-dimethyl acetamide (DMAc, Wako Pure Chemical Industries, Ltd.) was added and stirred at a room temperature, thereby preparing a uniform solution. While the solution was stirred, 64.6 g (0.416 mol) of 2-methacryloyloxyethyl isocyanate (trade name: KARENZ MOI, Showa Denko K. K.) was dropped. Subsequently, 0.79 g (1.25×10⁻³ mol) of di(n-butyl)tin dilaurate (Tokyo Chemical Industry Co., Ltd.) suspended in 30 g of DMAc was dropped. While being stirred, the mixture was heated to 65° C. in a water bath. The heating was stopped after 5 hours, and the mixture was naturally-cooled to a room temperature. The acid value of the reaction liquid was 7.105 mmol/g and the solid content thereof was 11.83%.

300 g of the reaction liquid was put in a beaker, and was then cooled by an ice bath to 5° C. While the reaction liquid was stirred, 41.2 ml of a quaternary normal sodium hydrateaqueous solution was dropped for approximately one hour. During dropping, the temperature of the reaction liquid was in a range of 5 to 11° C. After dropping, the reaction solution was stirred at a room temperature for 10 minutes, and solid components were removed by suctioning filtration, thereby obtaining a brown solution. The solution was reprecipitated by 3 liters of ethyl acetate and was filtered to obtain a deposited solid. The solid was reslurried all night by 3 liters of aceton. The solid was vacuum-dried for 10 hours after the filtration of the solid, thereby obtaining thin brown powder P-1. 1 g of the polymer was dissolved in a mixture solvent that was formed of 2 g of water and 1 g of acetonitrile. In this case, pH of the solution was 5.56, and the viscosity thereof was 5.74 (viscosity was measured at 28° C. using a viscometer (trade name: RE80, manufactured by Toki Sangyo Co. Ltd. A rotor 30XR14 was used)). Further, the molecular weight by GPC was 30000.

After the (c) reactive polymer compound containing layer was formed on the (b) chemically active site generating layer, exposure was performed from the side of the (c) reactive polymer compound containing layer at a room temperature for 1 minute, using ultraviolet light having a wavelength of 254 nm as energy for generating active sites and adhering by an exposure device: ultraviolet lamp (trade name: UVX-02516S1LP01, manufactured by Ushio Inc.). After exposure was performed on the entire surface of the layer, unnecessary reactants of the (c) reactive polymer compound containing layer not interacting with the (b) chemically active site generating layer were sufficiently cleaned and removed with 1% sodium bicarbonate liquid.

The board where the (c) reactive polymer compound containing layer was adhered to the (b) chemically active site generating layer was immersed in an aqueous solution of 0.1% by mass of silver nitrate (manufactured by Wako Pure Chemical Industries, Ltd.) for one hour, and then washed with distilled water. Subsequently, the board was immersed in an electroless plating bath having the following composition, thereby forming an electroless copper plating layer used as the seed. The thickness of the electroless plating layer was 1.5 microns.

<Ingredients of Electroless Plating Bath>

| | |
|---|---|
| Copper sulfate | 0.35 g |
| Tartaric acid NaK | 1.75 g |
| Sodium hydroxide | 0.75 g |
| Formaldehyde | 0.25 g |
| Water | 47.8 g |

Via holes, which were used to connect to an inner layer board of a lower layer, were formed in the board in which the electroless copper plating layer was formed as a surface layer. The via holes were formed using UV-YAG laser (generated from a device (trade name: LAVIA-UV2000, manufactured by Sumitomo Heavy Industries, Ltd.)) at an oscillation frequency of 4000 Hz so that the conductor layer of the lower layer appeared. Then, in order to remove smears remaining in the holes, a swelling process using an organic solvent-based swelling liquid was performed at 60° C. for 5 minutes, an etching process using a sodium permanganate-based etchant was performed at 80° C. for 10 minutes, and a neutralizing process using a sulfuric acid-based neutralizing liquid was performed at 40° C. for 5 minutes.

In addition, electroless copper plating was performed on the via holes by a process using an activator or an accelerator, which were generally available to the market.

A dry plating resist film was laminated on the board so as to have a thickness of 20 μm, and a substrate where a resist film was provided on a metal film was adhered to a mask film or a dry plate. Then, exposure was performed using light corresponding to exposing regions of the resist so that portions having wiring corresponded to openings, and the resist in the openings was dissolved and removed using an alkaline developer so that the conductor layer appeared to the outside. Further, when the wiring patterns were formed, a resist opening was particularly formed to measure the adhesion strength between the conductor layer and the board and form a portion having a dimension of 5 mm×10 cm in the conductor layer. Furthermore, patterns having a conductor of which values of a line/space were 10/10 μm were tentatively formed.

After the patterns were formed, electroplating was performed for 20 minutes in an electrolytic copper plating bath having the following composition under conditions of 3 A/dm² while the electroless copper plating layer provided below the patterns was used as a power feed layer. At the same time, a conductor layer was formed on the via holes due to the electroplating. As a result, the connection to the lower layer was achieved.

<Composition of Electroplating Bath>

| | | |
|---|---|---|
| Copper sulfate | 38 | g |
| Sulfuric acid | 95 | g |
| Hydrochloric acid | 1 | mL |
| Copper sulphate gloss agent (tradename: | 3 | mL |
| Coppergrim PCM, manufactured by Meltex, Inc.) | | |
| Water | 500 | g |

A heat treatment was performed at 140° C. for one hour on the board where the conductor layer was formed.

Subsequently, electroplating was performed to complete the metal patterns (conductor layer). Then, an unnecessary plating resist was stripped. The stripping was performed while a stripping solution was sprayed.

Next, the electroless plating layer, which was provided below the wiring patterns and used as the power feed layer during the electroplating process, was removed by performing wet etching (using an etchant containing ferric chloride as a main component, an etchant containing cupric chloride as a main component, or the like). In this case, copper formed on the portion corresponding to the wiring patterns was etched at the same time. However, the thickness of the portion was a sum of the thickness of the conductor layer and the thickness of the power feed layer. Accordingly, if the copper layer exposed to the outside is uniformly etched by a thickness of approximately 2 μm, the only desired wiring patterns remains and the power feed layer between wiring is removed.

Subsequently, in order to roughen the portions not having wiring, a swelling process using an organic solvent-based swelling liquid was performed at 60° C. for 5 minutes, an etching process using a sodium permanganate-based etchant was performed at 80° C. for 10 minutes, and a neutralizing process using a sulfuric acid-based neutralizing liquid was performed at 40° C. for 5 minutes were performed. After the processes were completed, a heat treatment was performed at 140° C. for one hour, thereby removing moisture contained in the board. The cross section of the board was inspected using an electron microscope to find out whether the (c) reactive polymer compound containing layer remains in the portion not having wiring. It was confirmed that the (c) reactive polymer compound containing layer did not remain in the portion not having wiring.

(Evaluation of a Ahesiveness)

A 90 degree-stripping test was performed with a TENSILON tensile tester (trade name: AGS-J, manufactured by Shimadzu Corporation) on a portion of the conductor layer, which was formed of copper and had a dimension of 5 mm×10 cm, in the resultant board having wiring patterns.

(Evaluation of Adhesion Between Adjacent Resin Layers)

Further, a GX-13 manufactured by Ajinomoto Fine-Techno Co. Inc. was laminated thereon in a vacuum under the same conditions as described above. The adhesion thereof was evaluated by performing a solder float test (a board was floated in a solder tank (260° C.) for 10 seconds and visual observation and micro session were performed at 10 points). Results of every evaluation were as follows: if stripping or blistering between two layers did not occur, the evaluation result was referred to as “A” for every evaluation. Even though stripping or blistering were not verified in visual observation, the evaluation result was referred to as “B to A” if swelling and the like were observed at one or two points by micro session. Even though stripping or blistering was not verified in visual observation, the evaluation result was referred to as “B” if swelling was observed at three points or more by micro session.

As a result, it was confirmed that sufficient adhesion strength was achieved between the electrical insulating layer of the lower layer and the electrical insulating layer of the upper layer in the multilayer wiring board according to Example 1.

(Evaluation of Pattern Formability)

Patterns having obtained line/space of 10/10 μm were observed using an electron microscope.

If line/space of design values was formed and the flatness of the formed conductor layer (line) was excellent, the evaluation result was referred to as “A”. If the shape of the line had linearity and flatness but was distorted partially, the evaluation result was referred to as “B”. If the shape of the line completely lacked linearity and flatness, the evaluation result was referred to as “C”.

(Ease of Forming Holes)

Ease of forming holes was evaluated by visually observing the shape of the formed hole. In the evaluation, ten holes were formed in each sample. If each of the holes had the shape of a complete circle or the shape similar to a complete circle, the evaluation result was referred to as “A”. If one or two holes had the shape of a slightly irregular circle, the evaluation result was referred to as “B to A”. If three holes or more had the shape of a slightly irregular circle, the evaluation result was referred to as “B”.

### Example 2

In a process, where light energy was applied to adhere the (c) reactive polymer compound containing layer to the (b) chemically active site generating layer, in Example 1, portions where via holes (holes) were intended to be formed were masked beforehand in a subsequent process so that both layers were not adhered to each other. Then, the same processes as those of Example 1 were performed. As a result, a board, which did not have a conductor layer at portions where holes were to be formed and had a conductor layer at other portions than the portions, were formed. Subsequently, similarly to Example 1, a hole forming process, a resist coating process, a pattern forming process, an electroplating process, a stripping process, and an etching process were sequentially performed on the board, and the board was evaluated in the same manner as Example 1.

It is found that, similarly to Example 1, the wiring board of Example 2 has excellent adhesion and conductivity. In addition, it is also found that holes can be more easily formed in the wiring board of Example 2, as compared with Example 1 and that few smears occurred.

### Example 3

An insulating resin composition having the following composition was used as the electrical insulating layer of Example 1.

Formation of Insulating Resin Composition

While 20 parts by mass of a bisphenol A epoxy resin (epoxy equivalent 185, trade name: EPIKOTE 828, manufactured byYuka Shell Epoxy Co., Ltd.) (hereinafter, the blending amount was described by parts by mass), 45 parts of a cresol novolac epoxy resin (epoxy equivalent 215, trade name: EPICLON N-673, manufactured by Dainippon Ink And Chemicals Inc.), and 30 parts of a phenol novolac resin (phenolic hydroxyl group equivalent 105, trade name: PHENOLITE, manufactured by Dainippon Ink And Chemicals Inc.) were dissolved with heating in 20 parts of ethyldiglycol acetate and 20 parts of solvent naphtha 20 while stirring. Then, the mixture was cooled to a room temperature. Subsequently, 30 parts of cyclohexanone varnish (trade name: YL6747H30, manufactured by Yuka Shell Epoxy Inc., nonvolatile ingredient 30% by mass, and average molecular weight 47000) of a phenoxy resin formed of the EPIKOTE 828 and the bisphenol S, 0.8 parts of 2-phenyl-4,5-bis(hydroxymethyl)imidazole, 2 parts of fine grinding silica, and 0.5 parts of a silicon-based anti-foaming agent were added to the mixture, thereby producing epoxy resin varnish. The insulating resin composition was coated on the board by a bar coater to have a thickness of 45 μm.

Subsequently, the (c) reactive polymer compound containing layer was formed in the same manner as Example 1, without forming the (b) chemically active site generating layer. The printed wiring board was formed in the same manner as Example 1, except that active sites were directly generated in the insulating resin composition by the irradiation of an ultraviolet ray having a wavelength of 172 nm in order to adhere the electrical insulating layer to the (c) reactive polymer compound containing layer. Then, the same tests as Example 1 were performed.

### Example 4

The printed wiring board was formed in the same manner as Example 1, except that a final roughening treatment was not performed on the portions not having wiring. Then, the same test as Example 1 was performed. The adhesion strength to the upper layer was slightly deteriorated, but it was enough to use.

### Comparative Example 1

The printed wiring board was formed in the same manner as Example 1, except that a roughening treatment using potassium permanganate was performed on the electrical insulating layer without forming the (b) chemically active site generating layer and the (c) reactive polymer compound containing layer, and then the electroless copper plating was then performed by a process using an activator or an accelerator, which were generally available to the market, to form the electroless plating layer used as the seed. Then, the same test as Example 1 was performed.

### Comparative Example 2

The printed wiring board was formed in the same manner as Example 1, except that without forming the (b) chemically active site generating layer and the (c) reactive polymer compound containing layer and performing a roughening treatment, the electroless copper plating was performed by a process using an activator or an accelerator, which were generally available to the market, to form the electroless plating layer used as the seed. Then, the same test as Example 1 was performed. Evaluation results were shown in Table 1.

TABLE 1

| | Adhesion | | Adhesion | Easy of |
|---|---|---|---|---|
| | strength | Forming ability of | to an upper | forming |
| | (kn/m) | Wiring patterns | layer | holes |
| Example 1 | 0.8 | A | A | BA |
| Example 2 | 0.78 | A | A | A |
| Example 3 | 0.89 | A | A | BA |
| Example 4 | 0.82 | A | BA | BA |
| Comparative | 0.85 | C | A | BA |
| example 1 | | (Wiring is uneven) | | |
| Comparative | 0.15 | B | B | BA |
| example 2 | | (Wiring floats and is | | |
| | | partially stripped) | | |

As shown in Table 1, it was understood that the multilayer wiring board obtained by the method according to the invention had high adhesion strength between a conductor layer and the board and fine wiring having excellent flatness. Meanwhile, according to a preferred embodiment, it was understood that via holes (holes) used for connection between layers could be easily formed in the multilayer wiring board.

According to the invention, it is possible to produce a multilayer wiring board where adhesion to an insulating film is excellent and a conductive layer having small irregularities on an interface between an insulating film and itself is easily formed on a surface of a predetermined solid.

Further, if the method of manufacturing the multilayer wiring board according to the invention is used, it is possible to easily form a multilayer wiring board, which includes high-definition wiring having excellent adhesion to an insulating film. The wiring board is useful for various electronic devices and electric devices, which each include a printed wiring board as a circuit.

It is advantageous in that the printed wiring board obtained by the invention includes fine wiring patterns having high frequency characteristics.

Hereinafter, embodiments of the invention will be listed. However, the invention is not restricted to the following embodiments.

[1] A multilayer wiring board comprising wiring patterns formed with a multilayer structure with at least one electrical insulating layer interposed therebetween, the wiring patterns being electrically connected with each other by at least one via formed in the insulating layer(s), the multilayer wiring board comprising at least one wiring containing layer on one side or both sides of a substrate, or of a circuit board having a predetermined wiring pattern, the wiring containing layer comprising:

a wiring forming layer, formed by disposing in this order
an insulating layer,
a chemically active site generating layer, and
a reactive polymer compound containing layer, and then applying energy to the wiring forming layer so as to cause interaction between the chemical active site generating layer and the reactive polymer compound containing layer; and

a conductor layer disposed on the wiring forming layer; wherein,

the chemically active site generating layer is able to interact with the insulating layer and is able to interact with the reactive polymer compound containing layer, and the reactive polymer compound containing layer is able to interact with the chemically active site generating layer and is able to interact with the conductor layer.

[2] A multilayer wiring board comprising wiring patterns formed with a multilayer structure with at least one electrical insulating layer interposed therebetween, the wiring patterns being electrically connected with each other by at least one via formed in the insulating layer(s), the multilayer wiring board comprising at least one wiring containing layer on one side or both sides of a substrate, or of a circuit board having a predetermined wiring pattern, the wiring containing layer comprising:

a wiring forming layer, formed by disposing in this order
an insulating layer having polymerization initiating ability and
a reactive polymer compound containing layer, and then applying energy to the wiring forming layer so as to cause interaction between the insulating layer having polymerization initiating ability and the reactive polymer compound containing layer; and

a conductor layer disposed on the wiring forming layer; wherein,

the insulating layer having polymerization initiating ability is able to interact with the reactive polymer compound containing layer, and the reactive polymer compound containing layer is able to interact with the insulating layer having polymerization initiating ability and is able to interact with the conductor layer.

[3] A method of manufacturing the multilayer wiring board according to [1], the method comprising:

forming an insulating layer by applying, to one side or both sides of a substrate, or of a circuit board having a predetermined wiring pattern, an electrical insulating layer forming material, and curing the material by energy application;

forming, on the insulating layer, a chemically active site generating layer, which can interact with the insulating layer and which can interact with a reactive polymer compound containing layer that can interact with a conductor layer;

forming, on the chemically active site generating layer, the reactive polymer compound containing layer, to which can be adhered a conductive material or a precursor thereof for forming the conductor layer;

adhering the reactive polymer compound containing layer to the chemically active site generating layer using interaction therebetween;

forming at least one hole in the laminate, which includes the insulating layer, the chemically active site generating layer, and the reactive polymer compound containing layer;

applying a conductive material, or a precursor thereof, to a polymer compound of the reactive polymer compound containing layer;

forming the conductor layer by performing plating using the conductive material, or the precursor thereof, that has been applied to the reactive polymer compound containing layer;

connecting a plurality of wiring lines to each other by applying a conductive material to the hole; and

performing heat treatment after the forming of the conductor layer.

[4] The method of manufacturing a multilayer wiring board according to [3], further comprising after the performing of the heat treatment after the forming of the conductor layer:

patterning the conductor layer by forming a layer of a plating resist or of an etching resist on the conductor layer and by performing a plating treatment or an etching treatment; and

removing unnecessary portions of the conductor layer after the patterning.

[5] A method of manufacturing the multilayer wiring board according to [2], the method comprising:

forming an insulating layer having polymerization initiating ability by applying, to one side or both sides of a substrate, or of a circuit board having a predetermined wiring pattern, an electrical insulating layer forming material containing a polymerization initiator, and curing the material by energy application;

forming on the insulating layer having polymerization initiating ability a reactive polymer compound containing layer, to which a conductive material or a precursor thereof for forming a conductor layer can be adhered;

adhering the reactive polymer compound containing layer to the insulating layer having polymerization initiating ability using interaction therebetween;

forming at least one hole in the laminate, which includes the insulating layer having polymerization initiating ability and the reactive polymer compound containing layer;

applying a conductive material, or a precursor thereof, to a polymer compound of the reactive polymer compound containing layer;

forming the conductor layer by performing plating with the conductive material, or the precursor thereof, that has been applied to the reactive polymer compound containing layer;

connecting a plurality of wiring lines to each other by applying a conductive material into the hole; and

performing heat treatment after the forming of the conductor layer.

[6] The method of manufacturing a multilayer wiring board according to [5], further comprising after the performing of the heat treatment after the forming of the conductor layer:

patterning the conductor layer by forming a layer of a plating resist, or of an etching resist, on the conductor layer and by performing a plating treatment or an etching treatment; and

removing unnecessary portions of the conductor layer after the patterning.

[7] The method of manufacturing a multilayer wiring board according to [3], wherein the adhering of the reactive polymer compound containing layer to the chemically active site generating layer, includes applying energy to the chemically active site generating layer.

[8] The method of manufacturing a multilayer wiring board according to [5], wherein the adhering of the reactive polymer compound containing layer to the insulating layer having polymerization initiating ability, includes applying energy to the insulating layer having polymerization initiating ability.

[9] The method of manufacturing a multilayer wiring board according to [3], wherein:

the reactive polymer compound containing layer contains 50% by weight or more, relative to the total solid content of the reactive polymer compound containing layer, of a polymer compound having a weight average molecular weight ranging from 1000 to 300000;

the polymer compound is adhered to the chemically active site generating layer by applying energy to the chemically active site generating layer; and

the adhesion is caused by a chemical bond.

[10] The method of manufacturing a multilayer wiring board according to [9], further comprising, after the applying of energy to the chemically active site generating layer:

removing at least a portion of the components that are contained in the reactive polymer compound containing layer that have no effect on adhesion.

[11] The method of manufacturing a multilayer wiring board according to [3], wherein one or more layers selected from the group consisting of the reactive polymer compound containing layer and the chemically active site generating layer are formed only on portion(s) where the conductor layer is to be formed.

[12] The method of manufacturing a multilayer wiring board according to [3], wherein region(s) for forming the hole(s) are region(s) where one or more layers selected from the group consisting of the reactive polymer compound containing layer and the chemically active site generating layer are not formed.

[13] The method of manufacturing a multilayer wiring board according to [4], further comprising, after patterning the conductor layer to form a wiring layer:

removing or inactivating the reactive polymer compound containing layer in a region where the wiring layer is not formed.

[14] The method of manufacturing a multilayer wiring board according to [5], wherein:

the reactive polymer compound containing layer contains 50% by weight or more, relative to the total solid content of the reactive polymer compound containing layer, of a polymer compound having a weight average molecular weight ranging from 1000 to 300000;

the polymer compound is adhered to the insulating layer having polymerization initiation ability by applying energy to the insulating layer having polymerization initiation ability; and

the adhesion is caused by a chemical bond.

[15] The method of manufacturing a multilayer wiring board according to [14], further comprising after the applying of energy to the insulating layer having polymerization initiation ability:

removing at least a portion of the components that are contained in the reactive polymer compound containing layer that have no effect on adhesion.

[16] The method of manufacturing a multilayer wiring board according to [5], wherein one or more layers selected from the group consisting of the reactive polymer compound containing layer and the insulating layer having polymerization initiation ability are formed only on portion(s) where a conductor layer is to be formed.

[17] The method of manufacturing a multilayer wiring board according to [5], wherein region(s) for forming the hole(s) are region(s) where one or more layers selected from the group consisting of the reactive polymer compound containing layer and the insulating layer having polymerization initiation ability are not formed.

[18] The method of manufacturing a multilayer wiring board according to [6], further comprising after patterning the conductor layer to form a wiring layer:

removing or inactivating the reactive polymer compound containing layer in a region where the wiring layer is not formed.

All publications, patent applications, and technical standards mentioned in this specification are herein incorporated by reference to the same extent as if each individual publication, patent application, or technical standard was specifically and individually indicated to be incorporated by reference.

What is claimed is:

1. A multilayer wiring board comprising wiring patterns formed with a multilayer structure with at least one electrical insulating layer interposed therebetween, the wiring patterns being electrically connected with each other by at least one via formed in the insulating layer(s), the multilayer wiring board comprising at least one wiring containing layer on one side or both sides of a substrate, or of a circuit board having a predetermined wiring pattern, the wiring containing layer comprising:
a wiring forming layer, formed by disposing in this order
an insulating layer,
a chemically active site generating layer, and
a reactive polymer compound containing layer, and then applying energy to the wiring forming layer so as to cause interaction between the chemical active site generating layer and the reactive polymer compound containing layer; and
a conductor layer disposed on the wiring forming layer; wherein,
the chemically active site generating layer is able to interact with the insulating layer and is able to interact with the reactive polymer compound containing layer, and the reactive polymer compound containing layer is able to interact with the chemically active site generating layer and is able to interact with the conductor layer.

2. A multilayer wiring board comprising wiring patterns formed with a multilayer structure with at least one electrical insulating layer interposed therebetween, the wiring patterns being electrically connected with each other by at least one via formed in the insulating layer(s), the multilayer wiring board comprising at least one wiring containing layer on one side or both sides of a substrate, or of a circuit board having a predetermined wiring pattern, the wiring containing layer comprising:
a wiring forming layer, formed by disposing in this order
an insulating layer having polymerization initiating ability and
a reactive polymer compound containing layer, and then applying energy to the wiring forming layer so as to cause interaction between the insulating layer having polymerization initiating ability and the reactive polymer compound containing layer; and
a conductor layer disposed on the wiring forming layer; wherein,
the insulating layer having polymerization initiating ability is able to interact with the reactive polymer compound containing layer, and the reactive polymer compound containing layer is able to interact with the insulating layer having polymerization initiating ability and is able to interact with the conductor layer.

3. A method of manufacturing the multilayer wiring board according to claim 1, the method comprising:
forming an insulating layer by applying, to one side or both sides of a substrate, or of a circuit board having a predetermined wiring pattern, an electrical insulating layer forming material, and curing the material by energy application;
forming, on the insulating layer, a chemically active site generating layer, which can interact with the insulating layer and which can interact with a reactive polymer compound containing layer that can interact with a conductor layer;
forming, on the chemically active site generating layer, the reactive polymer compound containing layer, to which can be adhered a conductive material or a precursor thereof for forming the conductor layer;
adhering the reactive polymer compound containing layer to the chemically active site generating layer using interaction therebetween;
forming at least one hole in the laminate, which includes the insulating layer, the chemically active site generating layer, and the reactive polymer compound containing layer;
applying a conductive material, or a precursor thereof to a polymer compound of the reactive polymer compound containing layer;
forming the conductor layer by performing plating using the conductive material, or the precursor thereof that has been applied to the reactive polymer compound containing layer;
connecting a plurality of wiring lines to each other by applying a conductive material to the hole; and
performing heat treatment after the forming of the conductor layer.

4. The method of manufacturing a multilayer wiring board according to claim 3, further comprising after the performing of the heat treatment after the forming of the conductor layer:
patterning the conductor layer by forming a layer of a plating resist or of an etching resist on the conductor layer and by performing a plating treatment or an etching treatment; and
removing unnecessary portions of the conductor layer after the patterning.

5. A method of manufacturing the multilayer wiring board according to claim 2, the method comprising:
forming an insulating layer having polymerization initiating ability by applying, to one side or both sides of a substrate, or of a circuit board having a predetermined wiring pattern, an electrical insulating layer forming material containing a polymerization initiator, and curing the material by energy application;
forming on the insulating layer having polymerization initiating ability a reactive polymer compound containing layer, to which a conductive material or a precursor thereof for forming a conductor layer can be adhered;
adhering the reactive polymer compound containing layer to the insulating layer having polymerization initiating ability using interaction therebetween;
forming at least one hole in the laminate, which includes the insulating layer having polymerization initiating ability and the reactive polymer compound containing layer;
applying a conductive material, or a precursor thereof to a polymer compound of the reactive polymer compound containing layer;
forming the conductor layer by performing plating with the conductive material, or the precursor thereof that has been applied to the reactive polymer compound containing layer;
connecting a plurality of wiring lines to each other by applying a conductive material into the hole; and
performing heat treatment after the forming of the conductor layer.

6. The method of manufacturing a multilayer wiring board according to claim 5, further comprising after the performing of the heat treatment after the forming of the conductor layer:
patterning the conductor layer by forming a layer of a plating resist, or of an etching resist, on the conductor layer and by performing a plating treatment or an etching treatment; and
removing unnecessary portions of the conductor layer after the patterning.

7. The method of manufacturing a multilayer wiring board according to claim 3, wherein the adhering of the reactive polymer compound containing layer to the chemically active site generating layer, includes applying energy to the chemically active site generating layer.

8. The method of manufacturing a multilayer wiring board according to claim 5, wherein the adhering of the reactive polymer compound containing layer to the insulating layer having polymerization initiating ability, includes applying energy to the insulating layer having polymerization initiating ability.

9. The method of manufacturing a multilayer wiring board according to claim 3, wherein:
the reactive polymer compound containing layer contains 50% by weight or more, relative to the total solid content of the reactive polymer compound containing layer, of a polymer compound having a weight average molecular weight ranging from 1000 to 300000;
the polymer compound is adhered to the chemically active site generating layer by applying energy to the chemically active site generating layer; and
the adhesion is caused by a chemical bond.

10. The method of manufacturing a multilayer wiring board according to claim 9, further comprising after the applying of energy to the chemically active site generating layer:
removing at least a portion of the components that are contained in the reactive polymer compound containing layer that have no effect on adhesion.

11. The method of manufacturing a multilayer wiring board according to claim 3, wherein one or more layers selected from the group consisting of the reactive polymer compound containing layer and the chemically active site generating layer are formed only on portion(s) where the conductor layer is to be formed.

12. The method of manufacturing a multilayer wiring board according to claim 3, wherein region(s) for forming the hole(s) are region(s) where one or more layers selected from the group consisting of the reactive polymer compound containing layer and the chemically active site generating layer are not formed.

13. The method of manufacturing a multilayer wiring board according to claim 4, further comprising after patterning the conductor layer to form a wiring layer:
removing or inactivating the reactive polymer compound containing layer in a region where the wiring layer is not formed.

14. The method of manufacturing a multilayer wiring board according to claim 5, wherein:
the reactive polymer compound containing layer contains 50% by weight or more, relative to the total solid content of the reactive polymer compound containing layer, of a polymer compound having a weight average molecular weight ranging from 1000 to 300000;
the polymer compound is adhered to the insulating layer having polymerization initiation ability by applying energy to the insulating layer having polymerization initiation ability; and
the adhesion is caused by a chemical bond.

15. The method of manufacturing a multilayer wiring board according to claim 14, further comprising after the applying of energy to the insulating layer having polymerization initiation ability:
removing at least a portion of the components that are contained in the reactive polymer compound containing layer that have no effect on adhesion.

16. The method of manufacturing a multilayer wiring board according to claim 5, wherein one or more layers selected from the group consisting of the reactive polymer compound containing layer and the insulating layer having polymerization initiation ability are formed only on portion(s) where a conductor layer is to be formed.

17. The method of manufacturing a multilayer wiring board according to claim 5, wherein region(s) for forming the hole(s) are region(s) where one or more layers selected from the group consisting of the reactive polymer compound containing layer and the insulating layer having polymerization initiation ability are not formed.

18. The method of manufacturing a multilayer wiring board according to claim 6, further comprising after patterning the conductor layer to form a wiring layer:
removing or inactivating the reactive polymer compound containing layer in a region where the wiring layer is not formed.
